(19) United States
(12) Patent Application Publication
(10) Pub. No.: US 2024/0282883 A1
(43) Pub. Date: Aug. 22, 2024

(54) METHOD FOR MANUFACTUING NON-EMITTING III-NITRIDE SEMICONDUCTOR STACKED STRUCTURE

(71) Applicant: WAVELORD CO., LTD, Suwon-si (KR)

(72) Inventor: June O SONG, Suwon-si (KR)

(73) Assignee: WAVELORD CO., LTD, Suwon-si (KR)

(21) Appl. No.: 18/570,666

(22) PCT Filed: Jun. 15, 2022
(86) PCT No.: PCT/KR2022/008481

§ 371 Date: Dec. 15, 2023

(30) Foreign Application Priority Data
Jun. 15, 2021 (KR) 10-2021-0077162
Jun. 29, 2021 (KR) 10-2021-0084975
Jul. 8, 2021 (KR) 10-2021-0089396
Jul. 14, 2021 (KR) 10-2021-0092370
Aug. 9, 2021 (KR) 10-2021-0104297
Aug. 19, 2021 (KR) 10-2021-0109671
Oct. 1, 2021 (KR) 10-2021-0130849
Oct. 15, 2021 (KR) 10-2021-0137660
Nov. 26, 2021 (KR) 10-2021-0164995
Dec. 3, 2021 (KR) 10-2021-0172292
Dec. 20, 2021 (KR) 10-2021-0182971
Dec. 30, 2021 (KR) 10-2021-0193217
Jan. 21, 2022 (KR) 10-2022-0008989
Apr. 21, 2022 (KR) 10-2022-0049342

(51) Int. Cl. H01L 33/00; H01L 21/02; H01L 25/075; H01L 29/20; H01L 29/66

(52) U.S. Cl. CPC H01L 33/007; H01L 21/02458; H01L 21/0254; H01L 25/0753; H01L 29/2003; H01L 29/66462; H01L 33/0093

(57) ABSTRACT

The present disclosure relates to a method for manufacturing a non-emitting III-nitride semiconductor stacked structure, the method comprising the steps of: preparing a growth substrate containing silicon (Si); forming a plurality of protrusions on the growth substrate; growing a first buffer layer to cover the plurality of protrusions on the growth substrate; forming a plurality of growth prevention films on the first buffer layer, growing a second buffer layer from the first buffer layer exposed through the growth prevention films; and forming a non-emitting III-nitride semiconductor stacked structure on the second buffer layer.

### DESCRIPTION

### Technical Field

The present disclosure overall relates to a non-emitting III-nitride semiconductor stacked structure or a III-nitride semiconductor device, and a method of manufacturing the same, and particularly, to a non-emitting III-nitride semiconductor stacked structure or III-nitride semiconductor device such as a power device (e.g., a transistor or HEMT) and a method of manufacturing the same. In addition, a part of the present disclosure is able to be expanded to an emitting III-nitride semiconductor stacked structure or a III-nitride semiconductor device (e.g., an LED or LD), and a method of manufacturing the same.

### Background Art

This section provides background information related to the present disclosure which is not necessarily prior art.

FIG. 1 is a diagram illustrating an example of a III-nitride semiconductor device disclosed in U.S. Pat. No. 7,230,284, wherein the III-nitride semiconductor device (e.g., AlGaN/GaN-based HEMT) includes a growth substrate 11 (e.g., a sapphire substrate or an SiC substrate), a buffer layer 12 (e.g., AlxGa1−xN (0≤x≤1) buffer layer), a channel layer 20 (e.g., a GaN channel layer), a two-dimensional electron gas (2DEG) 22, a barrier layer 18 (e.g., an AlGaN barrier layer), an insulating layer 24 (e.g., an SiN insulating layer), a drain electrode 14, a gate electrode 16, and a source electrode 17.

In terms of material costs and crystallinity, it is preferable that a sapphire substrate is utilized as a growth substrate 11, but it is not suitable in terms of heat dissipation. A SiC substrate can be a consideration in terms of crystallinity and heat dissipation. However, it requires a high material cost, and it may be difficult to make it larger. To reduce material costs, the use of a less expressive Si substrate may be considered, and a method to improve the crystallinity of a III-nitride semiconductor layer that grows on this substrate must be involved. During the growth process, a method of improving the crystallinity of a III-nitride semiconductor layer will be first described below.

FIG. 2 is a diagram illustrating an example of a III-nitride semiconductor stacked structure disclosed in U.S. Patent Laid-Open Publication No. 2005-0156175, wherein the III-nitride semiconductor stacked structure includes a c-face sapphire substrate 100, growth prevention films 150 formed of SiO2 on the c-face sapphire substrate 100, and a III-nitride semiconductor layer 310 selectively grown thereon. According to the growing method, crystal defects in the III-nitride semiconductor stacked structure may be reduced.

FIG. 3 is a diagram illustrating another example of a III-nitride semiconductor stacked structure disclosed in U.S. Patent Laid-Open Publication No. 2005-0156175, wherein the III-nitride semiconductor stacked structure includes a c-face sapphire substrate 100, a III-nitride semiconductor template 210 formed on the c-face sapphire substrate 100, growth prevention films 150 formed of SiO2 on the III-nitride semiconductor template 210, and a III-nitride semiconductor layer 310 selectively grown thereon. The III-nitride semiconductor template 210 is formed by a conventional method of growing a III-nitride semiconductor on a c-face sapphire substrate 100. In other words, at a growth temperature of approximately 550° C. and in a hydrogen atmosphere, a seed layer is formed, and then grown to a thickness of 1 to 3 μm according to a method of growing GaN at a growth temperature of 1050° C. Reference numeral 180 indicates defects (threading dislocations), and by preventing the development of defects under the growth prevention films 150, overall crystallinity is improved. In other words, the growth prevention film 150 enables epitaxially lateral overgrowth (ELOG) as in the III-nitride semiconductor stacked structure shown in FIG. 1 and also serves to block the defects 180 occurring below.

FIG. 4 is a diagram illustrating an example of a III-nitride semiconductor light emitting diode disclosed in U.S. Patent Laid-Open Publication No. 2003-0057444, wherein the III-nitride semiconductor light emitting diode includes a sapphire substrate 100, an n-type III-nitride semiconductor layer 300 grown on the sapphire substrate 100, an active layer 400 grown on the n-type III-nitride semiconductor layer 300, and a p-type III-nitride semiconductor layer 500 grown on the active layer 400. Protrusions 110 are formed on the sapphire substrate 100, and they improve the growth quality of the III-nitride semiconductor layers 300, 400, and 500 formed on the sapphire substrate 100 and serve as a scattering surface that improves the efficiency of emitting light generated in the active layer 400 to the outside of the light emitting device. Such a sapphire substrate 100 having the protrusions 110 is called a patterned sapphire substrate (PSS).

FIG. 5 is a diagram illustrating an example of a III-nitride semiconductor light emitting diode disclosed in U.S. Patent Laid-Open Publication No. 2005-082546, wherein the III-nitride semiconductor light emitting diode includes a sapphire substrate 101 having protrusions 111 and a III-nitride semiconductor layer 301. Unlike the example shown in FIG. 4, the protrusions 111 have a round cross-section. In the case of the protrusions 110 shown in FIG. 4, epitaxial growth occurs on both the bottom surface (corresponding to the concave parts of the concavo-convex structure that forms the protrusions 110) and the top surface of the protrusions 110, causing threading dislocations, which are crystal defects, on both the bottom and top surfaces. On the other hand, the use of the protrusions 111 with a round cross-section has the advantage of suppressing the epitaxial growth on the top surface of the protrusions 111 and suppressing threading dislocations.

FIG. 6 is a diagram illustrating an example of a III-nitride semiconductor light emitting diode disclosed in U.S. Patent Laid-Open Publication No. 2011-0042711, wherein the III-nitride semiconductor light emitting diode 10 includes a sapphire substrate 11, an n-type III-nitride semiconductor region 12a grown on the sapphire substrate 11, an active region 12b grown on the n-type III-nitride semiconductor region 12a, and a p-type III-nitride semiconductor region 12c grown on the active region 12b. Likewise, protrusions 13 are formed on the sapphire substrate 11. However, the protrusions 13 have a pointed cross-section. When the pointed protrusions 13 are used, the upper part of the protrusions 13 is formed as a dot or line (when the protrusions 13 are formed in a conical shape, the upper part of the protrusion 13 is formed as a dot, and when the protrusions 13 are formed in a pointed stripe shape, the upper part of the protrusion 13 becomes a line), resulting in suppression of the formation of threading dislocations. Meanwhile, by suppressing the epitaxial growth on the side connecting the top and the bottom surfaces of the protrusion 13, the occurrence of the threading dislocations on the side thereof may also be suppressed.

FIG. 7 is a diagram illustrating an example of a III-nitride semiconductor stacked structure disclosed in U.S. Pat. No. 10,361,339, wherein the III-nitride semiconductor stacked structure includes a sapphire substrate 10, a buffer region 20, and a III-nitride semiconductor region 30. It is shown that threading dislocations 35 are still formed on the upper part of the protrusions even with the form of protrusions shown in FIG. 6.

FIGS. 26 and 27 are diagrams illustrating an example of a III-nitride semiconductor stacked structure or device disclosed in U.S. Pat. No. 9,324,844, and show a vertical junction field effect transistor (JFET) 1000 as a non-emitting III-nitride semiconductor stacked structure or device. The non-emitting III-nitride semiconductor device 1000 includes a drain region 102, a drift region 103, a gate region 104, a source region 105, a drain electrode 106, a gate electrode 107, and a source electrode 108. FIG. 26 shows an OFF state as a default mode, in which a depletion region 109 overlaps in a channel 121 (see FIG. 27) at position 120 and prevents current from flowing. FIG. 27 shows an ON state, in which when voltages (VD,VS) are applied to the gate electrode 107 and the source electrode 108, the gate voltage (VD) reduces the size of the depletion region 109 to provide the channel 121 through which current can flow, thereby turning on the vertical JFET 1000, and the depletion region 109 is separated, allowing the current to flow in the vertical direction 122 from the drain region 102 to the source region 105 via the drift region 103 and the channel region 121.

FIG. 41 is a diagram illustrating an example of a non-emitting III-nitride semiconductor stacked structure or device disclosed in U.S. Pat. No. 7,388,236, wherein like the device shown in FIG. 1, the III-nitride semiconductor device (e.g., AlGaN/GaN-based HEMT) includes a growth substrate 11 (e.g., a sapphire substrate or a SiC substrate), a buffer layer 12 (e.g., an AlxGa1−xN (0≤x≤1) buffer layer), a channel layer 20 (e.g., a GaN channel layer), a two-dimensional electron gas (2DEG) 22, a barrier layer 18 (an AlGaN barrier layer), an insulating layer 24 (an SiN insulating layer), a drain electrode 14, a gate electrode 16, and a source electrode 17, and further includes a gate field plate 25 on the gate electrode 16. Meanwhile, as another conducive III nitride layer 26 (e.g., p-type GaN) is included between the gate electrode 16 and the barrier layer 17, depletion-mode (D-mode) AlGaN/GaN HEMT (a device that is in a turn-on state, i.e., normally-on state when a gate voltage is not applied) can be implemented as enhancement-mode (E-mode) HEMT (a device that is in a turn-off state, i.e., a normally-off state when a gate voltage is not applied). When high electrical energy (high voltage, high frequency) is supplied (or injected) through the gate electrode 16, a large electric field is concentrated around the gate electrode 16, giving an electrical impact to a part of the III-nitride semiconductor device, which has a negative effect on the lifetime and reliability of the device. To prevent this negative effect, the gate field plate 25 is designed as an electrode plate extending from the gate electrode 16 to distribute the concentrated electrical field and protect the device.

FIG. 57 is a diagram illustrating an example of a display device disclosed in U.S. Patent Laid-Open Publication No. 2021-0183301, wherein the display device 4100 includes a first sub pixel (SP1), a second sub pixel (SP2), and a third sub pixel (SP3). In addition, the display device 4100 includes a support substrate 4110 (e.g., a backplane board), a driving layer 4130 disposed on the substrate 4110, and light emitting units 4141, 4142, 4143, 4145, 4146, 4147, 4149, and 4150 disposed on the driving layer 4130. The driving layer 4130 may operate light emitting units and may be formed of a driving element 4135 and an insulating layer 4132, wherein the driving element 4135 may be formed of a transistor, a thin film transistor, or a high electron mobility transistor (HEMT). The light emitting unit 4141 is a first electrode, the light emitting unit 4142 is a first semiconductor layer, the light emitting unit 4143 is an active layer, the light emitting unit 4145 is a second semiconductor layer, the light emitting unit 4146 is a second electrode, the light emitting unit 4147 is an isolation structure, the light emitting unit 4149 is a window region, and the light emitting unit 4150 is a reflective layer. Of course, the light emitting units can be formed of OLEDs as well as LEDs and micro LEDs.

FIGS. 58 and 59 are diagrams illustrating an example of a display device disclosed in Korean Patent Laid-Open Publication No. 10-2021-0023392, wherein the display device 5150 includes light emitting units 151, 153, and 155, a pad electrode PAD, a buffer layer 5120, passivation layers 162 and 164, a switching transistor SMT, a driving transistor DRT, a storage capacitor Cst, and an encapsulation layer 180b. The light emitting unit 151 is a first semiconductor layer, the light emitting unit 153 is an active layer, and the light emitting unit 155 is a second semiconductor layer. The switching transistor SMT includes a first heterojunction layer 165a, a first gate electrode 167a, a first source electrode 168a, and a first drain electrode 169a. The first heterojunction layer 165a includes a first channel-forming layer 161a and a first channel-providing layer 163a. The driving transistor DRT includes second heterojunction layer 165b, a second gate electrode 167b, a second source electrode 168b, and a second drain electrode 169b. The second heterojunction layer 165b includes a second channel-forming layer 161b and a second channel-providing layer 163b. The storage capacitor Cst includes a first storage electrode 171, a dielectric layer 173, and a second storage electrode 175. The first storage electrode 171 is connected to the first drain electrode 169a of the switching transistor SWT, and the second storage electrode 175 is connected to the second source electrode 168b of the driving transistor DRT. The pad electrode PAD is connected to a power interconnection Vdd (see FIG. 59) to which a voltage or signal for driving a sub pixel is applied, and S-PAD is a source pad electrode that allows the first source electrode 168a to be connected to a data interconnection DL. In FIG. 59, GL is a gate interconnection to which the first gate electrode 167a of the switch transistor SWT is connected, and Vcom is a common interconnection to which the second source electrode 168b of the driving transistor DRT is connected. In summary, the first gate electrode 167a of the switching transistor SWT is connected to the gate interconnection GL, the first source electrode 168a is connected to the data interconnection DL, the first drain electrode 169a is connected to the second gate electrode 167b of the driving transistor DRT, the second source electrode 168b is connected to the common interconnection Vcom, the second drain electrode 169b is connected to the first semiconductor layer 151, the pad electrode PAD is connected to the power interconnection Vdd, and the storage capacitor Cst is connected to the first drain electrode 169a and the second source electrode 168b. By the above interconnections, light emission of the light emitting units (μLED) 151, 153, and 155 was controlled. As the switching transistor SWT and the driving transistor DRT, various forms of transistors such as BJT, MOSFET, and TFT may be used, but in the present examples, HEMT was used.

### DISCLOSURE

### Technical Problem

This will be described in the latter part of ‘Specific Details for Carrying Out the Invention.’

### Technical Solution

This section provides a general summary of the disclosure and is not a comprehensive disclosure of its full scope or all of its features.

According to one aspect of the present disclosure, provided is a method of manufacturing a non-emitting III-nitride semiconductor stacked structure, which includes preparing a growth substrate containing silicon (Si); forming a plurality of protrusions on the growth substrate; growing a first buffer layer to cover the plurality of protrusions on the growth substrate; forming a plurality of growth prevention films on the first buffer layer; growing a second buffer layer from the first buffer layer exposed through the growth prevention films; and forming a non-emitting III-nitride semiconductor stacked structure on the second buffer layer.

According to another aspect of the present disclosure, provided is a method of manufacturing a non-emitting III-nitride semiconductor stacked structure, which includes preparing a growth substrate; forming a plurality of protrusions on the growth substrate; growing a first buffer layer to cover the plurality of protrusions on the growth substrate; forming a plurality of growth inhibition films on the first buffer layer; growing a second buffer layer from the first buffer layer exposed through the plurality of growth inhibition films; and forming a non-emitting III-nitride semiconductor stacked structure on the second buffer layer.

According to still another aspect of the present disclosure, provided is a method of manufacturing a non-emitting III-nitride semiconductor stacked structure, which includes preparing a growth substrate; growing a first buffer layer on the growth substrate; forming a plurality of protrusions formed of the same material as the first buffer layer on the first buffer layer; growing a second buffer layer on the first buffer layer; forming a non-emitting III-nitride semiconductor stacked structure on the second buffer layer; and forming a material layer that allows the growth of the second buffer layer to be slower or prevented on the plurality of protrusions before growing the second buffer layer.

According to yet another aspect of the present disclosure, provided is a non-emitting III-nitride semiconductor stacked structure, which includes a drain region; a drift region; and a gate region, which are sequentially stacked; a support substrate electrically connected to the drain region; a gate electrode electrically connected to the gate region; a source electrode electrically connected to a channel formed by the drift region exposed through the gate region; a passivation layer that covers the entire stacked structure where the gate electrode and the source electrode are located and in which a plurality of openings are formed; a gate electrode for bonding, which is electrically connected to the gate electrode by one of the plurality of openings; and a source electrode for bonding, which is electrically connected to the source electrode by another of the plurality of openings.

According to yet another aspect of the present disclosure, provided is a method of manufacturing a non-emitting III-nitride semiconductor stacked structure, which includes forming a non-emitting III nitride stacked structure on a growth substrate; attaching a temporary substrate to the stacked structure facing the growth substrate; removing the growth substrate; forming a multilayer thin film including an electrically insulating ceramic layer and a metal layer on the growth substrate-removed stacked structure in the order of the ceramic layer and the metal layer; attaching a support substrate to the multilayer thin film; and removing the temporary substrate.

According to another aspect of the present disclosure, provided is a stacked structure for a non-emitting III-nitride semiconductor, which includes a support substrate; a multilayer thin film consisting of an electrically insulating ceramic layer and a metal layer, which are sequentially stacked; a non-emitting III-nitride semiconductor region that consists of a buffer layer, a channel layer, and a barrier layer; a gate electrode, a source electrode, and a drain electrode, which are electrically connected to the non-emitting III-nitride semiconductor region; a passivation layer that covers the non-emitting III-nitride semiconductor region where the source electrode, the drain electrode and the gate electrode are located and exposes the source electrode, the drain electrode, and the gate electrode to enable electrical connection to the outside; and a field plate disposed on the upper part of the passivation layer to be electrically connected to one of the source electrode and the gate electrode.

According to yet another aspect of the present disclosure, provided is a method of manufacturing a non-emitting III-nitride semiconductor stacked structure, which includes forming a non-emitting III nitride stacked structure on a non-conductive growth substrate; attaching a temporary substrate to the side of the stacked structure facing the growth substrate; reducing the thickness of the growth substrate; attaching a support substrate to the thickness-reduced growth substrate; and removing the temporary substrate.

According to yet another aspect of the present disclosure, provided is a method of manufacturing a non-emitting III-nitride semiconductor stacked structure, which includes sequentially growing a drain region and a drift region; forming a channel by removing a part of the drift region; and regrowing a gate region in the partially-removed drift region, and further includes forming an interlayer between the gate region and the drift region before the regrowing.

According to yet another aspect of the present disclosure, provided is a method of manufacturing a non-emitting III-nitride semiconductor stacked structure, which includes preparing a growth substrate including a plurality of protrusions; growing a first buffer layer to cover the plurality of protrusions on the growth substrate; forming a plurality of growth prevention films without an alignment process with respect to the plurality of protrusions on the first buffer layer; and growing a second buffer layer from the first buffer layer exposed through the plurality of growth prevention films.

According to yet another aspect of the present disclosure, provided is a method of manufacturing a non-emitting III-nitride semiconductor stacked structure, which includes forming a channel layer, a 2DEG, a barrier layer, and a gate electrode on a growth substrate; attaching a temporary substrate using a junction layer; removing the growth substrate; and forming a source electrode and a drain electrode on the channel layer from which the growth substrate is removed.

According to yet another aspect of the present disclosure, provided is a method of manufacturing a non-emitting III-nitride semiconductor stacked structure, which includes forming a seed layer formed of AlN at a first temperature on a growth substate formed of silicon (Si); forming an AlN layer at a second temperature higher than the first temperature on the seed layer; forming a channel layer, a 2DEG, and a barrier layer on the AlN layer; and forming at least one of an air void and a protrusion before forming the channel layer.

According to yet another aspect of the present disclosure, provided is a method of manufacturing a non-emitting III-nitride semiconductor device, which includes growing a non-emitting III-nitride semiconductor stacked structure on a growth substrate formed of sapphire; attaching a temporary substrate to the non-emitting III-nitride semiconductor stacked structure on the side facing the growth substrate; removing the growth substrate from the non-emitting III-nitride semiconductor stacked structure; attaching a support substrate formed of silicon to the non-emitting III-nitride semiconductor stacked structure on the side from which the growth substrate is removed; and removing the temporary substrate from the non-emitting III-nitride semiconductor stacked structure.

According to yet another aspect of the present disclosure, provided is a method of manufacturing a non-emitting III-nitride semiconductor device, which includes forming a trench in one surface of a growth substrate; filling the trench with a trench-covering material; forming a seed layer on one surface of the growth substate while filling the trench with the trench-covering material; forming a non-emitting III-nitride semiconductor stacked structure on the seed layer; exposing the trench by reducing the thickness of the growth substrate; and forming a conductive material in the trench from which the trench-covering material is removed.

According to yet another aspect of the present disclosure, provided is a method of manufacturing a III-nitride semiconductor stacked structure, which includes forming a first seed layer on a growth substrate, wherein the first seed layer has a composition that allows the growth substrate to have a concave shape; forming a first layer on the first seed layer, wherein the first layer has a composition that allows the growth substrate on which the first seed layer is formed to be less concave; forming a second layer of a Ga-rich III-nitride semiconductor on the first layer; forming a plurality of protrusions on the second layer; forming a second seed layer on the second layer on which the plurality of protrusions are formed, wherein the second seed layer has a composition that applies stress such that the growth substrate on which the second layer provided with the plurality of protrusions is formed is concave; forming a stress adjustment layer on the second seed layer, wherein the stress adjustment layer has an Al composition that releases or strengthens stress depending on a bowing state of the growth substrate on which the second seed layer is formed to prevent cracks in the stacked structure after forming an uppermost layer; and forming an uppermost layer of Ga-rich III-nitride semiconductor on the stress adjustment layer.

### Advantageous Effects

This will be described in the latter part of ‘Specific Details for Carrying Out the Invention.’

### DESCRIPTION OF DRAWINGS

FIG. 1 is a diagram illustrating an example of a III-nitride semiconductor device disclosed in U.S. Pat. No. 7,230,284.

FIG. 2 is a diagram illustrating an example of a III-nitride semiconductor stacked structure disclosed in U.S. Patent Laid-Open Publication No. 2005-0156175.

FIG. 3 is a diagram illustrating another example of a III-nitride semiconductor stacked structure disclosed in U.S. Patent Laid-Open Publication No. 2005-0156175.

FIG. 4 is a diagram illustrating an example of a III-nitride semiconductor light emitting diode disclosed in U.S. Patent Laid-Open Publication No. 2003-0057444.

FIG. 5 is a diagram illustrating an example of a III-nitride semiconductor light emitting diode disclosed in U.S. Patent Laid-Open Publication No. 2005-082546.

FIG. 6 is a diagram illustrating an example of a III-nitride semiconductor light emitting diode disclosed in U.S. Patent Laid-Open Publication No. 2011-0042711.

FIG. 7 is a diagram illustrating an example of a III-nitride semiconductor stacked structure disclosed in U.S. Pat. No. 10,361,339.

FIG. 8 is a diagram illustrating an example of a III-nitride semiconductor stacked structure or device according to the present disclosure.

FIG. 9 is a diagram illustrating an example of the arrangement relationship between protrusions and growth preventions films according to the present disclosure.

FIG. 10 is a diagram illustrating an example of a method of forming protrusions on a growth substrate according to the present disclosure.

FIG. 11 is a diagram illustrating another example of a method of forming protrusions on a growth substrate according to the present disclosure.

FIG. 12 is a diagram illustrating still another example of a method of forming protrusions

on a growth substrate according to the present disclosure.

FIG. 13 is a diagram illustrating yet another example of a method of forming protrusions on a growth substrate according to the present disclosure.

FIG. 14 is a diagram illustrating a specific example of the method of forming protrusions shown in FIG. 12.

FIGS. 15 to 17 are diagrams illustrating an example of a method of forming growth prevention films according to the present disclosure.

FIG. 18 is a diagram illustrating another example of a method of forming growth prevention films according to the present disclosure.

FIG. 19 is a diagram illustrating still another example of a method of forming a growth prevention film according to the present disclosure.

FIG. 20 a diagram illustrating yet another example of a method of forming growth prevention films according to the present disclosure.

FIGS. 21 to 23 are diagrams illustrating yet another example of a method of forming growth prevention films according to the present disclosure.

FIGS. 24 and 25 are diagrams illustrating another example of a III-nitride semiconductor stacked structure or device according to the present disclosure.

FIGS. 26 and 27 are diagrams illustrating an example of a III-nitride semiconductor stacked structure or device disclosed in U.S. Patent Publication No. 9,324,844.

FIGS. 28 to 37 are diagrams illustrating an example of a method of manufacturing a III-nitride semiconductor stacked structure or device according to the present disclosure.

FIGS. 38 to 40 are diagrams illustrating an example of a support substrate used in the stacked structure shown in FIG. 37.

FIG. 41 is a diagram illustrating an example of a non-emitting III-nitride semiconductor stacked structure or device disclosed in U.S. Pat. No. 7,388,236.

FIGS. 42 to 46 are diagrams illustrating an example of a method of manufacturing the non-emitting III-nitride semiconductor stacked structure or device shown in FIG. 41.

FIG. 47 is a diagram illustrating an example of a method of manufacturing a non-emitting III-nitride semiconductor stacked structure or device according to the present disclosure.

FIG. 48 is a diagram illustrating another example of a method of manufacturing a non-emitting III-nitride semiconductor stacked structure or device according to the present disclosure.

FIG. 49 is a diagram illustrating still another example of a method of manufacturing a non-emitting III-nitride semiconductor stacked structure or device according to the present disclosure.

FIG. 50 is a diagram illustrating yet another example of a method of manufacturing a non-emitting III-nitride semiconductor stacked structure or device according to the present disclosure.

FIG. 51 is a diagram illustrating yet another example of a method of manufacturing a non-emitting III-nitride semiconductor stacked structure or device according to the present disclosure.

FIGS. 52 and 53 are diagrams illustrating yet another example of a method of manufacturing a III-nitride semiconductor stacked structure or device according to the present disclosure.

FIGS. 54 and 55 are diagrams illustrating other examples of the arrangement relationship between protrusions and growth prevention films according to the present disclosure.

FIG. 56 illustrates an example of a monochromatic CL image illustrating crystal defects formed in a first buffer layer.

FIG. 57 is a diagram illustrating an example of the display device disclosed in U.S. Patent Laid-Open Publication No. 2021-0183301.

FIGS. 58 and 59 are diagrams illustrating an example of the display device disclosed in Korean Patent Laid-Open Publication No. 10-2021-0023392.

FIG. 60 is a diagram illustrating yet another example of a method of manufacturing a non-emitting III-nitride semiconductor stacked structure or device according to the present disclosure.

FIGS. 61 and 62 are diagrams illustrating various forms of the non-emitting III-nitride semiconductor stacked structure or device manufactured by the method shown in FIG. 60.

FIG. 63 is a diagram illustrating an example of a method of transferring the non-emitting III-nitride semiconductor stacked structure or device manufactured by the method shown in FIG. 60.

FIG. 64 is a diagram illustrating another example of a method of transferring the non-emitting III-nitride semiconductor stacked structure or device manufactured by the method shown in FIG. 60.

FIG. 65 is a diagram illustrating still another example of a non-emitting III-nitride semiconductor stacked structure or device according to the present disclosure.

FIG. 66 is a diagram illustrating wafer bowing during the growth of the non-emitting III-nitride semiconductor stacked structure or device shown in FIG. 65.

FIG. 67 is a diagram illustrating yet another example of a non-emitting III-nitride semiconductor stacked structure or device according to the present disclosure.

FIG. 68 is a diagram illustrating wafer bowing during the growth of the non-emitting III-nitride semiconductor stacked structure or device shown in FIG. 67.

FIG. 69 is a diagram illustrating yet another example of a non-emitting III-nitride semiconductor stacked structure or device according to the present disclosure.

FIG. 70 is a diagram illustrating wafer bowing during the growth of the non-emitting III-nitride semiconductor stacked structure or device shown in FIG. 69.

FIG. 71 is a diagram illustrating yet another example of a non-emitting III-nitride semiconductor stacked structure or device according to the present disclosure.

FIG. 72 is a diagram illustrating wafer bowing during the growth of the non-emitting III-nitride semiconductor stacked structure or device presented FIG. 71.

FIGS. 73 and 74 are diagrams illustrating yet another example of manufacturing a non-emitting III-nitride semiconductor stacked structure or device according to the present disclosure.

FIGS. 75 to 87 are diagrams illustrating yet another example of manufacturing a non-emitting III-nitride semiconductor stacked structure or device according to the present disclosure.

FIGS. 88 to 92 are diagrams illustrating yet another example of a III-nitride semiconductor stacked structure or device according to the present disclosure.

### MODES OF THE INVENTION

The present disclosure will now be described in detail with reference to the accompanying drawing(s).

FIG. 8 is a diagram illustrating an example of a III-nitride semiconductor stacked structure or device according to the present disclosure, and as an example, HEMT is presented. The III-nitride semiconductor device includes a growth substrate 42 (a 6- or 8-inch Si substrate) having protrusions 41, a first buffer layer 43, growth prevention films 44 (e.g., a dielectric material such as SiO2 or SiNx), a second buffer layer 45, a channel layer 46 (e.g., a 3-μm GaN channel layer), a 2DEG 47, an interlayer 48 (e.g., a 10-nm thin AlN layer, can be omitted), a barrier layer 49 (e.g., a 10 to 50-nm AlxGa1−xN (0.2≤x≤0.3˜0.6), AlGaInN, or AlScN barrier layer), a cap layer 50 (e.g., a 5 to 20-nm GaN cap layer, able to be doped with an n or p layer, can be omitted), a source electrode 51, a gate electrode 52, and a drain electrode 53.

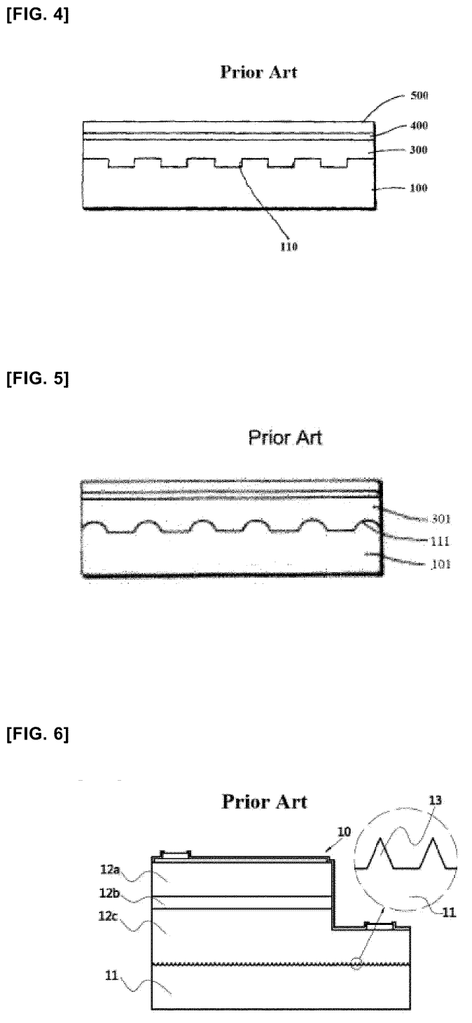

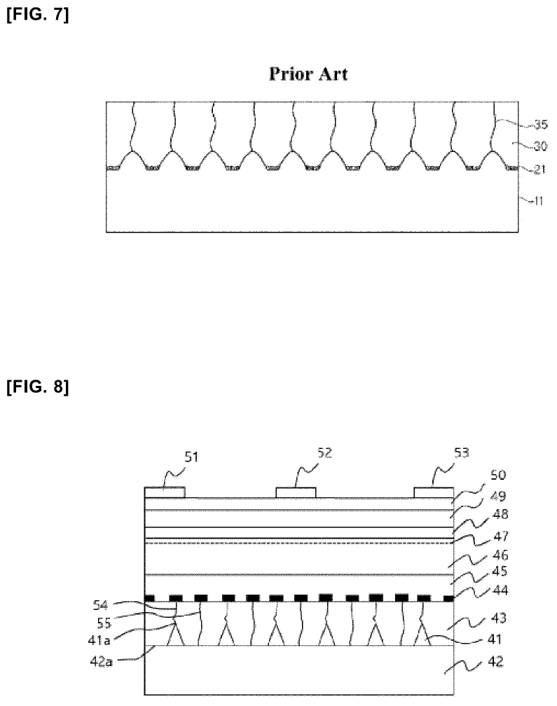

Since the growth substrate 42 made of silicon (Si) (hereinafter, referred to as the Si growth substrate 42) is an opaque substrate, protrusions used in a sapphire substrate (see FIGS. 4 to 7; these protrusions primarily serve as a scatterer (light scatterer) for eliminating total internal reflection caused by the difference in refractive index between the III-nitride semiconductor layer and the sapphire substrate in the light emitting device (LED), and secondarily serve as growth prevention films (see FIGS. 2 and 3) in ELOG, resulting in enhanced film quality) are not needed. However, to enhance the film quality in the non-emitting III-nitride semiconductor device or stacked structure according to the present disclosure, the protrusions 41 are used even for the Si growth substrate 42. In addition, as previously pointed out, even when using the protrusions 41, crystal defects, particularly, threading dislocations 54 and 55 are generated in the first buffer layer 43 from an upper part or top surface 41a of the protrusions 41 and the bottom surface of the growth substrate 42 to the bottom surface 42a of the protrusions 41, and when high quality, that is, a threading dislocation density (TDD) of 107/cm2 or less, is required, it is difficult to achieve the high quality. To address this problem, in the present disclosure, the protrusions 41 are formed on the Si growth substrate 42, the growth prevention films 44 are formed on the first buffer layer 43 to block a part of the threading dislocations 54 and 55 present in the first buffer layer 43, and the III-nitride semiconductor stacked structure including the second buffer layer 45, the channel layer 46, and the barrier layer 48 is formed thereon, so the film quality thereof has a TDD of 107/cm2 or less. When the device requires high heat dissipation specifications, the growth substrate 42 may be changed from the Si growth substrate to a SiC growth substrate, and thus a growth substrate containing Si (a Si growth substrate or a SiC growth substrate) may be used as the growth substrate 42. The protrusions 41 may have various forms as shown in FIGS. 4 to 7, and to minimize the threading dislocations 54 on the upper part or top surface 41a of the protrusions 41, it is preferable for the longitudinal cross-section to have a pointed shape. Depending on the structure and shape of the protrusions 41, the material that constitutes the protrusions 41 may be the same material (e.g., Si or SiC) as the growth substrate 42, or a different material (e.g., AlN, AlNO, AlGaN, or GaN) from the growth substrate 42.

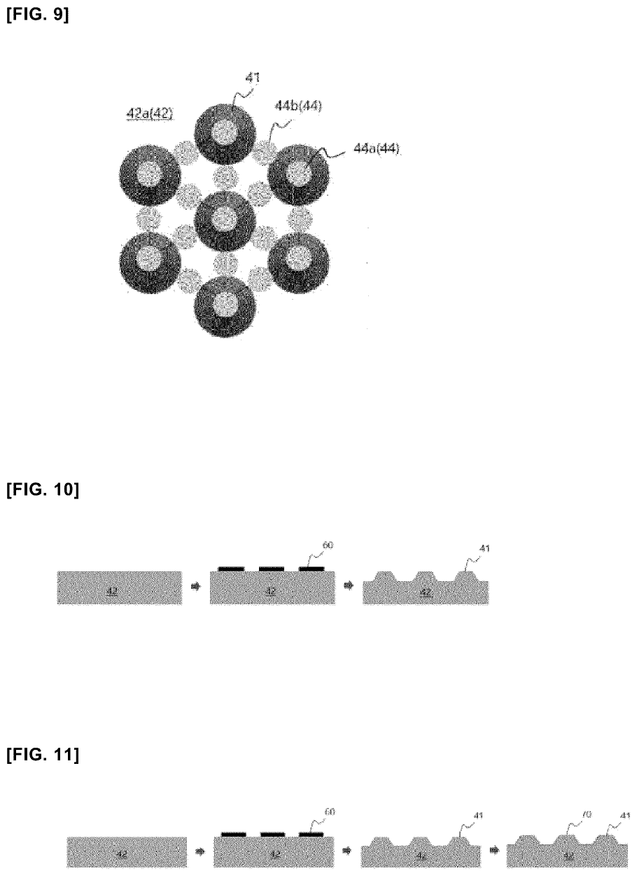

FIG. 9 is a diagram illustrating an example of the arrangement relationship between protrusions and growth prevention films according to the present disclosure, which is a top view of the growth substrate 42 or the protrusions 41 that are formed on the bottom surface 42a of the growth substrate 42. The conical protrusions 41 with a round cross-section are arranged at regular intervals in the diagonal direction, the growth prevention films 44 disposed on the protrusions 41 are indicated by 44a, and the growth prevention films 44 disposed on the bottom surface 42a are indicated by 44b. Threading dislocations 54 are blocked by a growth prevention film 44a, and a part of threading dislocations 55 are prevented by a growth prevention film 44b. The size of the growth prevention films 44a is preferably smaller than that of the cross-section of the protrusions 41 on the bottom surface 42a, and this is because when the growth prevention films 44a becomes too large, the region where a second buffer layer 45 will grow is excessively reduced.

The protrusion 41 may have a height of 0.1 to 2 μm, a width of 0.2 to 3.0 μm, and an interval of 0.1 to 1.0 μm, and the longitudinal cross-section thereof may have a cone, square pyramid, dome, or truncated cone/pyramid shape.

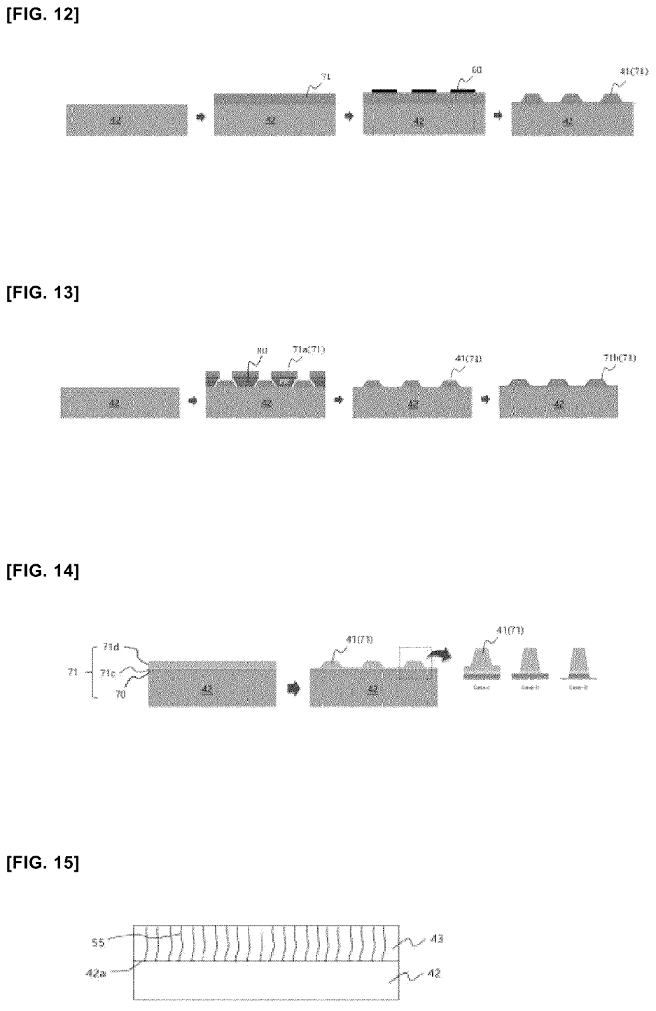

Before growing the first buffer layer 43, depending on the type (Si or SiC) of growth substrate 42, regardless of the presence or absence of the protrusions 41 (in the examples shown in FIGS. 10 and 11, the protrusions 41 are first formed, and in the examples shown in FIGS. 12 and 13, the protrusions 41 are formed later), a GaN, AlN, AlNO, or AlGaN seed layer (not shown) having a thickness of approximately 20 nm may be formed by a CVD (MOCVD, ALD, or MBE) or PVD (sputtering or PLD) method. Particularly, when an AlN seed layer is formed on the Si growth substrate 42 by a CVD method, it is also preferable that a pre-seeding process in which TMAl gas, which is an aluminum (Al) source, is supplied alone without supplying ammonia (NH3) gas, which is a nitrogen (N) source, is introduced. To grow the first buffer layer 43 formed of a III-nitride semiconductor on the Si growth substrate 42, since the minimum actual growth temperature is high, such as 800° C. or more, an Si atom is released from the surface of the Si growth substrate 42 through atomic debonding and desorption, and fine amorphous material particles are generated by Si—N bonding on the Si surface in a high-temperature nitrogen atmosphere, making it difficult to obtain a high-quality III-nitride semiconductor thin film. To effectively inhibit this, when an aluminum (Al) pre-seeding process is introduced onto the surface of the Si growth substrate 42 from several to tens of seconds, it is advantageous for growing the III-nitride semiconductor thin film. After forming a seed layer (not shown) on the Si growth substrate 42, in a subsequent process, the first buffer layer 43 may be grown into GaN or Ga-rich AlGaN using a GaN monolayer, an AlN monolayer, or a multilayer thin film such as TMGa or TMAl, NH3 as a source gas, and hydrogen (H2) as a carrier gas in an actual growth temperature range of 800 to 1100° C. under a relatively high pressure (e.g., 250 mbar), and on the other hand, grown into AlN or Al-rich AlGaN under a relatively low pressure (e.g., 50 mbar). In some cases, an AlGaN layer formed by alloying GaN and AlN may be introduced into a part of the first buffer layer 43. That is, the first buffer layer 43 may be formed of GaN, GaN/AlGaN, AlN, AlN/AlGaN, AlN/AlGaN/GaN, or GaN/AlGaN/AlN on the growth substrate 42.

The thickness of the first buffer layer 43 has to be higher than the height of the protrusion 41, and to primarily shield and reduce threading dislocations generated by the difference in lattice constant with the growth substrate 42, after growing the first buffer layer 43 to at least the same height as or higher than the protrusion 41, it is very important that as the growth rate in a horizontal direction is set to be greater than that in the vertical direction, and it is very important to bend threading dislocations that move in a vertical direction, parallel to the growth. The condition for growing to the height of the protrusion 41 is preferably a greater growth rate in a vertical direction than that in a horizontal direction. In a wafer state where the first buffer layer 43 is grown on the growth substrate 42, bowing may occur, which may interfere with accurate positioning of the growth prevention films 44. When considering this bowing, the thickness of the first buffer layer 43 may be limited to less than 3 μm. Therefore, the height of the protrusions 41 may be limited to less than the thickness of the first buffer layer 43.

The growth prevention films 44 may be formed to a thickness of 1 nm to 1 μm, and as long as the growth of the second buffer layer 45 may be inhibited, its thickness is not particularly limited. The shape of the growth prevention films 44 is a strip mask shape using a dielectric such as SiO2 or SiNx in a conventional ELOG or pseuto-III nitride growth process (e.g., Pendeo Epitaxy), and the positions of the growth prevention films 44 are a region aligned in the center of the protrusions 41 where the growth prevention films 44a are located and a region aligned with the bottom surface of the growth substrate 42 between the protrusions 41 where the growth prevention films 44b are located. For example, the protrusions 41 have isolated or island shapes of circles, triangles, quadrangles, and hexagons with various dimensions. The width of the growth prevention films 44a aligned with the protrusions 41 is primarily determined according to the shape and dimensions of the protrusions 41, but ultimately, the width of the growth prevention films 44a is preferably determined by considering the position and distribution of threading dislocations formed during the growth of the first buffer layer 43

Like the first buffer layer 43, the second buffer layer 45 may be grown into GaN or Ga-rich AlGaN using a GaN monolayer, an AlN monolayer, or TMGa or TMAl as a multilayer thin film, NH3 as a source gas, and hydrogen (H2) as a carrier gas in an actual growth temperature range of 800 to 1100° C. under a relatively high pressure (250 mbar), and on the other hand, grown into AlN or Al-rich AlGaN under a relatively low pressure (50 mbar). In some cases, an AlGaN layer formed by alloying GaN and AlN may be introduced into a part of the second buffer layer 45. In other words, the second buffer layer 45 may be formed of GaN, GaN/AlGaN, AlN, AlN/AlGaN, AlN/AlGaN/GaN, or GaN/AlGaN/AlN on the first buffer layer 43 and the growth prevention films 44. The thickness of the second buffer layer 45 is basically larger than that of the growth prevention films 44. Generally, the second buffer layer 45 may be grown to have a thickness of 1 to 5 μm. The threading dislocations occurring on the growth substrate 42 are secondarily shielded and dissipated by the growth prevention films 44, and a III-nitride semiconductor having considerably fewer threading dislocations is regrown in a region of the first buffer layer 43 where the growth prevention films 44 are not formed to form the second buffer layer 45 through ELOG or a growth process similar thereto. The foundation for manufacturing a III-nitride semiconductor stacked structure or device having a threading dislocation density (TDD) of 107/cm2 or less, which is the purpose of the present disclosure, may be created.

FIG. 10 is a diagram illustrating an example of a method of forming protrusions on a growth substrate according to the present disclosure. First, a growth substrate 42 is prepared, an etch mask 60 is formed, and protrusions 41 are formed through dry etching or wet etching of the growth substrate 42 itself. In one example, after forming the etch mask 60 with SiO2 or SiNx on the (100), (110), or (111) surface of the Si growth substrate, the protrusions 41 may be formed in various shapes and dimensions by combining a KOH wet solution and dry etching.

FIG. 11 is a diagram illustrating another example of a method of forming protrusions on a growth substrate according to the present disclosure. The method of FIG. 11 includes forming a seed layer 70 (AlN, AlNO, Al2O3, or Ga2O3) to cover the entire surface of the growth substrate 42 having protrusions 41, in addition to the method shown in FIG. 10. The seed layer 70 may be formed by PVD, and serves to help the growth of a first buffer layer 43 that is grown by CVD (e.g., MOCVD).

FIG. 12 is a diagram illustrating still another example of a method of forming protrusions on a growth substrate according to the present disclosure. Unlike the method shown in FIG. 11, after preparing a growth substrate 42, a protrusion base layer 71 is formed, an etch mask 60 is formed thereon, and then a part of the protrusion base layer 71 is etched to form protrusions 41. Accordingly, the protrusions 41 are formed of a material for forming the protrusion base layer 71 formed on the growth substrate 42, rather than a material formed of the growth substrate 42. Here, since a first buffer layer 43 is formed over the entire protrusion base layer 71 by performing etching without exposing the growth substrate 42, high film quality can be achieved. The protrusion base layer 71 may be formed of a seed layer 70 (see FIG. 11) and a III-nitride semiconductor layer (e.g., AlGaN or GaN) disposed thereon, as described above, the seed layer 70 may be formed of AlN, AlNO, Al2O3, or Ga2O3 with a thickness of 200 nm or less by a PVD or CVD method, and the III-nitride semiconductor layer may be formed as a multilayer film in which AlGaN and GaN are sequentially stacked with a thickness of 3 μm or less by a CVD method, and serve as a strain control layer. The protrusion base layer 71 for forming the protrusions 41 may be etched until the seed layer 70 is exposed. In one example, as the seed layer 70, 150 nm thick AlN (in some cases, a pre-seeding process using a TMAl gas can be introduced to a pre-seeding process using a TMAl gas) is formed on the growth substrate 42 by a CVD (MOCVD) method, and then the III-nitride semiconductor layer may be formed as a multilayer composed of two regions (first and second). The first layer may be formed of AlxGa1−xN with a thickness of 500 nm. The first layer is formed while sequentially reducing an aluminum (Al) composition (x) from 80% to 20% to primarily release tensile stress. The second layer may be formed of GaN with a thickness of 2 μm. Subsequently, after forming the etch mask 60 formed of a material such as SiO2 or SiNx, protrusions 41 are formed by dry etching.

FIG. 13 is a diagram illustrating yet another example of a method of forming protrusions on a growth substrate according to the present disclosure. Unlike the methods shown in FIGS. 11 and 12, a seed layer 70 (see FIG. 11) is formed by a lift-off method, rather than etching. After preparing a growth substrate 42, a patterned photoresist (PR) film 80 is formed, a part of a protrusion base layer 71 (e.g., an AlN, AlNO, Al2O3, or Ga2O3 layer having a thickness of 2 μm or less, indicated by 71a) is formed by a PVD method, and when the photoresist film 80 is removed, the protrusion base layer 71a formed on the photoresist film 80 is also removed, and thus the residual protrusion base layer 71a remains in the form of a protrusion 41 on the growth substrate 42. Subsequently, a protrusion base layer (71; an AlN, AlNO, Al2O3, or Ga2O3 layer having a thickness of 1 μm or less, indicated by 71b) serving as a seed layer 70 (see FIG. 11) is formed again by a PVD method. Here, the protrusion base layer 71b is formed to cover the entire surface of the growth substrate 42, helping the growth of a first buffer layer 43. The thicknesses of the layers 71a and 71b, which constitute the protrusion base layer 71, are preferably set to minimize wafer bowing caused by stress to the growth substrate 42. In one example, the thickness of the protrusion base layer 71a formed on the photoresist film 80 may be 500 nm, and the thickness of the protrusion base layer 71a may be 20 nm.

FIG. 14 is a diagram illustrating a specific example of the method of forming protrusions shown in FIG. 12, and illustrates a process of sequentially forming a protrusion base layer 71 on a growth substrate 42 by sequentially disposing a seed layer 70 (AlN with a thickness of 200 nm or less), a first layer 71c (AlxGa1−xN with a thickness of 500 nm) and a second layer 71d (GaN with a thickness of 2 μm), and forming protrusions 41 from the protrusion base layer 71. Here, the protrusions 41 may be formed from only a second layer 71d (Case I), from a first layer 71c-second layer 71d (Case II), or a seed layer 70-first layer 71c-second layer 71d (Case III).

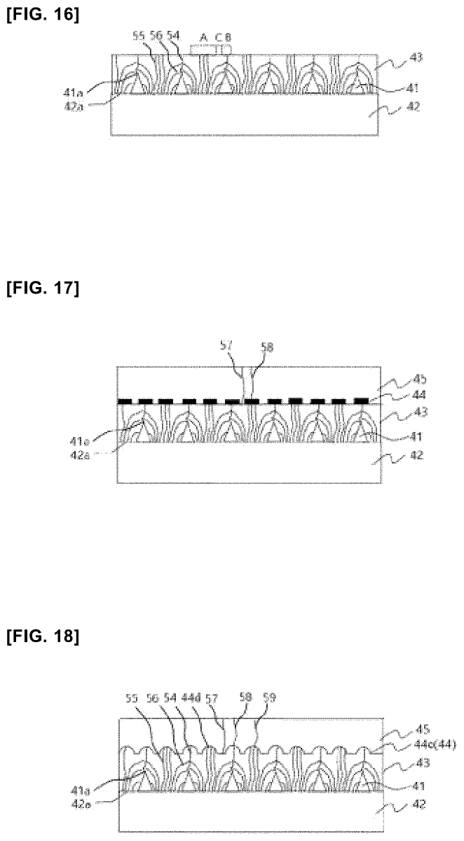

FIGS. 15 to 17 are diagrams illustrating an example of a method of forming growth prevention films according to the present disclosure. In FIG. 15, a growth substrate 42 and a first buffer layer 43 grown thereon are illustrated. On the growth substrate 42, no protrusions 41 (see FIG. 8) are formed, and threading dislocations 55 are formed through the first buffer layer 43 over the entire bottom surface 42a of the growth substrate 42. FIG.16 shows the growth substrate 42 having the protrusions 41 and the first buffer layer 43 grown thereon. On the bottom surface 42a (region A) of the growth substrate 42 having no protrusions 41, as shown in FIG. 15, the threading dislocation 55 is formed through the first buffer layer 43, and on the upper part or top surface 41a(region B) of the protrusion 41, a threading dislocation 54 is also formed through the first buffer layer 43. The threading dislocation 54 may directly occur from the upper part or top surface 41a, or may occur when the first buffer layer 43 grown from the bottom surface 42a coalesces at the upper part or top surface 41a of the protrusion 41, that is, in region B. By forming the upper part or the top surface 41a of the protrusion 41 in a pointed shape, the threading dislocation 54 directly occurring from the upper part or top surface 41a may be minimized. In region C between region A and region B, a bowed threading dislocation 56 is formed. The threading dislocation 56 is formed in a bowed shape in the process of filling a space (concave part) between the protrusions 41 with the first buffer layer 43 grown from the bottom surface 42a of the growth substrate 42, and when growth conditions are appropriately adjusted, most of the threading dislocations do not extend to the upper part of the first buffer layer 43, so they are not considered to crystal defects in a second buffer layer 45 (see FIG. 8) formed thereon. Meanwhile, threading dislocations may be generated on the side of the protrusions 41 (that is, the protrusion 41 region between the bottom surface 42a and the upper part or top surface 41a), and as shown in FIGS. 5 to 7, may be minimized by allowing the side of the protrusions 41 not to be a crystal surface (e.g., in the case of a sapphire growth substrate 41, mainly, a c-face is used as the bottom surface 42a). In other words, the growth of the first buffer layer 43 on the side of the protrusions 41 may be inhibited by making the cross-section of the side of the protrusions 41 circular and the longitudinal section thereof linear or convex-shaped, or applying roughening to the side of the protrusions 41. Accordingly, when the first buffer layer 43 is grown on the growth substrate 42 having the protrusions 41, it can be seen that region C can be grown as a region with less crystal defects, compared to region A and region B. Therefore, in the example shown in FIG. 17, the growth prevention films 44 are formed in regions A and B, the material for forming the growth substrate 42 may be sapphire (Al2O3) as well as Si and SiC, or may be sapphire with an HCP crystal structure, AlN, AlGaN, or GaN, and as a surface where growth occurs, that is, the bottom surface 42a, a C-face may be used. The growth prevention films 44 disposed on region A (see FIG. 16) block threading dislocations 55, and the growth prevention films 44 disposed on region B (see FIG. 16) block threading dislocations 54. Since, due to the bowing of threading dislocations 56 occurring on region C (see FIG. 16), most of the dislocations 56 may not pass through the first buffer layer 43, the threading dislocations are minimized on the top surface of the first buffer layer 43, and thus the first buffer layer 43 exposed by the growth prevention films 44, that is, threading dislocations 57 and 58 in the second buffer layer 45 grown from the first buffer layer 43 corresponding to region C may be minimized to have a TDD of 107/cm2 or less. The threading dislocations 57 are threading dislocations occurring from the exposed first buffer layer 43. Since the exposed first buffer layer 43 already has film quality with minimized crystal defects and the threading dislocations 57 are grown therefrom, the number of crystal defects is greatly reduced. The threading dislocations 58 are crystal defects generated by coalescence of the second buffer layer 45 grown from the exposed first buffer layer 43 on the growth prevention films 44, and have a greatly reduced number compared to the threading dislocations 55 blocked by the growth prevention films 44. The protrusion 41 has a microscale width and height, such as 1 μm or more (e.g., width: 2.5 μm, height: 1.6 μm, and interval between the protrusions: 0.4 μm), or a nanoscale width and height, such as less than 1 μm (e.g., width: 500 nm, height: 500 nm, and interval between the protrusions: 50 nm). The protrusions 41 may be aligned in a stripe or dot shape. In the case in which the protrusions are aligned in a dot shape, six protrusions 41 may be placed at the vertices of a hexagon centered on one protrusion 41 (from the perspective of a row of the protrusions 41 (an array of dots), protrusions 41 belonging to the adjacent rows are not aligned with each other, but are arranged in a zigzag fashion). In addition, assuming that the first buffer layer 43 can be grown, it is preferable that the bottom surface 42a where growth occurs is minimized.

As described above, the growth prevention films 44 are formed of a dielectric such as SiO2 or SiN (thickness: 1 to 1000 nm) to inhibit the second buffer layer 45 on the growth prevention films 44. Alternatively, as the growth prevention films 44 are formed of a material that allows the growth of the second buffer layer 45, which is preferably a material that reduces the growth rate of the second buffer layer 45 (e.g., AlN, AlNO, or AlO), rather than a material forming the upper part of the first buffer layer 43 (e.g., GaN) (the growth prevention films 44 are formed by depositing AlN, AlNO, or AlO to a predetermined thickness (e.g., 1 to 100 nm) using a PVD (sputtering, ALD, or PLD) device and then patterning the deposited result), it may be formed to delay the growth of the second buffer layer 45 on the growth prevention films 44. When the growth prevention films 44 formed of a material that reduces the growth rate of the second buffer layer 45 (e.g., AlN, AlNO, or AlO) are used, like when the growth prevention films 44 formed of a dielectric are used, the second buffer layer 45 grown from the exposed first buffer layer 43 is propagated on the growth prevention films 44, but the second buffer layer 45 is also grown from the growth prevention films 44 (the growth prevention films 44 serve as a seed layer of the second buffer layer 45). Therefore, the growth prevention films 44 formed of a material that reduces the growth rate of the second buffer layer 45 (e.g., AlN, AlNO, or AlO) show a different behavior from the mechanism of threading dislocations generated through the coalescence of the second buffer layer 45 on the dielectric (SiO2 or SiNx) growth prevention films 44.

FIG. 18 is a diagram illustrating another example of a method of forming growth prevention films according to the present disclosure. Unlike the previous examples, the growth prevention films 44 are formed by the first buffer layer 43 itself. The growth prevention films 44 may be formed in the form of protrusions 44c in the same concept as the protrusion 41 formed on the growth substrate 42, and may be formed by a photolithography process and an etching process (plasma). The principle of reducing crystal defects in the second buffer layer 45 is the same as the previous examples. Threading dislocations 57 are threading dislocations that are present in a second buffer layer 45 on the first buffer layer 43 without protrusions 44c, and in region C (see FIG. 16), threading dislocations 54 in the first buffer layer 43 are bowed, so most of them do not continue to the upper part of the first buffer layer 43. Therefore, in this region, the second buffer layer 45 is grown from the first buffer layer 43 with high film quality and has fewer threading dislocations 57. Threading dislocations 58 are threading dislocations generated on the upper part or top surface 44d of protrusions 44c located at a position corresponding to the protrusions 41, threading dislocations 59 are threading dislocations generated on the upper part or top surface 44d of the protrusions 44c located at a position corresponding to the bottom surface 42a, and threading dislocations 55 present in the first buffer layer 43 extend to the protrusions 44c. However, the upper part or top surface 44d of the protrusions 44c has a narrow flat surface or is pointed, so it is difficult for the threading dislocations 55 to be present even in the second buffer layer 45. Some of the threading dislocations 58 and 59 are generated by the threading dislocations 54 and the threading dislocations 55, and some are generated on the upper part or top surface 44d of the protrusions 44c through coalescence of the second buffer layer 45 grown on the first buffer layer 43 without protrusions 44c. Compared to the example shown in FIG. 17, this is a homo-epitaxy forming process for forming protrusions 44c through a relatively easy process (photolithography or etching (plasma)) on a GaN or AlGaN single crystal (epitaxy) having an HCP crystal structure, and growing the second buffer layer with the same material (GaN or AlGaN), so it has the advantage in that threading dislocations and other crystal defects can be minimized. The protrusions 44c may have dimensions, which are the same as or similar to those of the protrusions 44a formed on the growth substrate 42, and preferably have a nanoscale width and a height of less than 1 μm (e.g., width: 500 nm, height: 500 nm, and interval between protrusions: 50 nm), rather than a microscale width and a height of 1 μm or more.

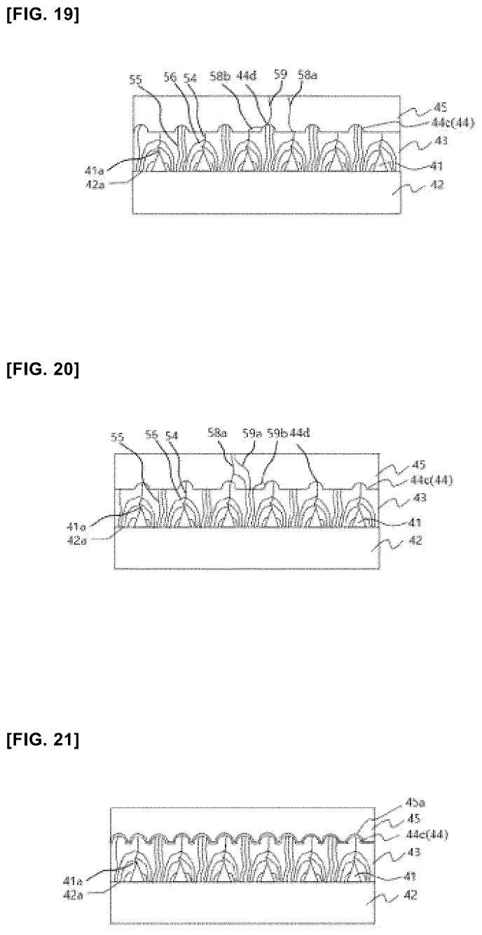

FIG. 19 is a diagram illustrating still another example of a method of forming growth prevention films according to the present disclosure. Unlike the example shown in FIG. 18, protrusions 44c forming growth prevention films 44 are formed on a first buffer layer 43 at a location corresponding to a bottom surface 42a of a growth substrate 42, that is, a location corresponding to region A. While threading dislocations 55 present in region A are connected to the protrusions 44c, the upper part or top surface 44d of the protrusions 44c is narrow or pointed, and thus the protrusions disappear, or only some extend to a second buffer layer 45, forming threading dislocations 59. Some of the threading dislocations 54 present in region B extend to the second buffer layer 45 to form threading dislocations 58a, or become bowed threading dislocations 58b in the process of filling a space between the protrusions 44c with the second buffer layer 45 and then disappear in the second buffer layer 45. Since there are fewer threading dislocations in region C, the generation of crystal defects is minimized even in the second buffer layer 45 grown from the region C.

FIG. 20 a diagram illustrating yet another example of a method of forming growth prevention films according to the present disclosure. Unlike the example shown in FIG. 18, protrusions 44c forming growth prevention films 44 are formed on a first buffer layer 43 at a location corresponding to the upper part or top surface 41a of protrusions 41, that is, a location corresponding to region B. Some of threading dislocations 55 present in region A extend to a second buffer layer 45 and are present as threading dislocations 59b, but some become bowed threading dislocations 59b in the process of filling a space between protrusions 44c with the second buffer layer 45 and then disappear in the second buffer layer 45. Threading dislocations 54 present in region B extend to the protrusions 44c, but since the upper part or top surface 44d of the protrusions 44c is narrow or pointed, the threading dislocations 54 disappear, or some extend to the second buffer layer 45 to form threading dislocations 58a. Since there are fewer threading dislocations in region C, the generation of crystal defects is minimized even in the second buffer layer 45 grown from the region C.

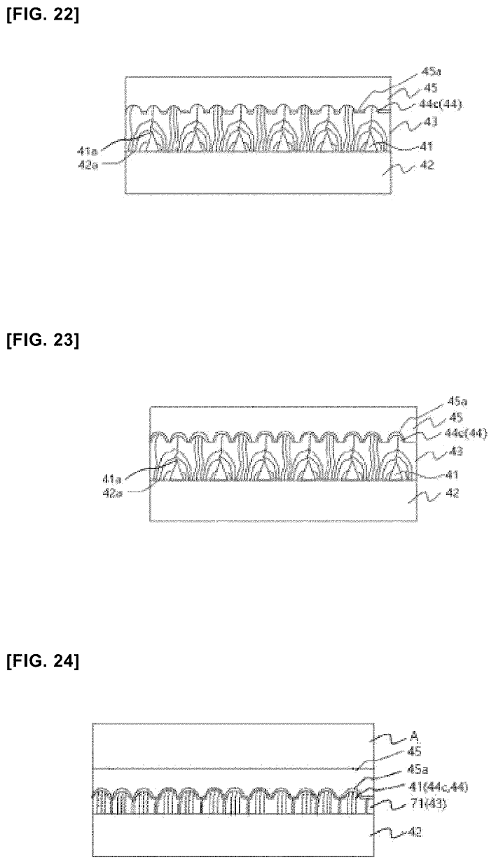

FIGS. 21 to 23 are diagrams illustrating yet another example of a method of forming growth prevention films according to the present disclosure. In FIG. 21, in addition to the components shown in FIG. 18, an AlN, AlNO, or AlO material layer 45a is formed on a first buffer layer 43 with protrusions 44c. The material layer 45a may be formed of the same material as the growth prevention films 44 shown in FIG. 17 to have a thickness of 1 to 100 nm in the same manner (deposited using a PVD (sputtering, ALD, or PLD) device). In FIG. 22, the material layer 45a is formed only in region A, and in FIG. 23, the material layer 45a is formed to cover at least some of the protrusions 44c. The material layer 45a shown in FIGS. 21 to 23 may also be applied to the configurations shown in FIGS. 19 and 20. By introducing the material layer 45a, threading dislocations that are generated from a growth substrate 42 and exposed to the surface of a first buffer layer 43 are blocked and reduced, and the second buffer layer 45 grown in both regions A and B (see FIG. 16) has a small difference in lattice constant with the material layer 45a formed of AlN, AlNO, or AlO, thereby suppressing the generation of threading dislocations and minimizing the overall number of threading dislocations. It is obvious that the material layer 45a can be introduced into the example shown in FIG. 17. The material layer 45a may also serve to repair defects that can be generated in the first buffer layer 43 exposed in the process of forming the growth prevention films 44 and the protrusions 44c.

Considering all of the examples shown in FIGS. 17 to 23, the growth prevention films 44 may be referred to as growth inhibition films 44 in that they prevent or slow the growth of the second buffer layer 45.

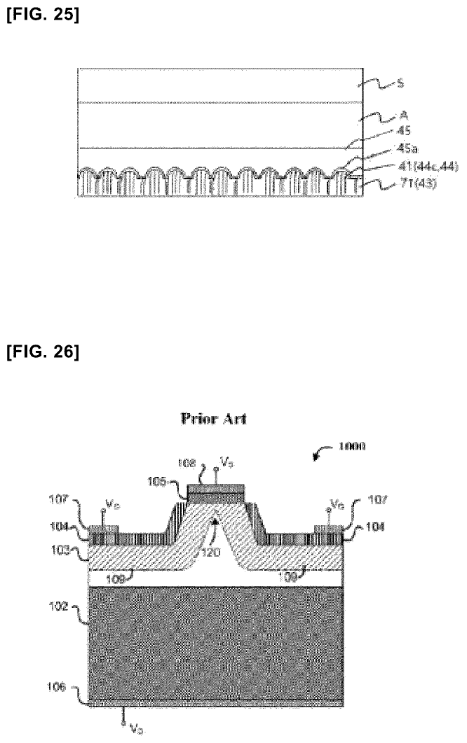

FIGS. 24 and 25 are diagrams illustrating another example of a III-nitride semiconductor stacked structure or device according to the present disclosure, and show an example in which the form of protrusions 41 shown in FIG. 14 and the material layer 45a shown in FIG. 21 are combined. In view of the example shown in FIG. 14, rather than forming protrusions 41 consisting of the material (Al2O3) forming a growth substrate 42 (see FIGS. 16 to 23) on the growth substrate 42 (e.g., sapphire substrate), a protrusion base layer 71 is formed through film formation and patterned to form protrusions 41, and then the material layer 45a shown in FIG. 21 is formed thereon. Here, the growth prevention films or growth inhibition layers 44 may be omitted, and the protrusion base layer 71 corresponds to a first buffer layer 43. In view of the example shown in FIG. 21, without protrusions 41 formed on a growth substrate 42, a first buffer layer 43 is formed, and then protrusions 44c are formed on the first buffer layer 43 as a growth inhibition layer 44, and then a material layer 45a is formed thereon. On top of this, a second buffer layer 45 and a non-emitting III-nitride semiconductor stacked structure or device A are stacked. It is obvious that the material layer 45a may be partially formed in the form as shown in FIGS. 22 and 23, and when the material layer 45a is formed in the same form as shown in FIG. 23, it is obvious that the material layer 45a may be formed on the protrusions 41 with a dielectric material such as SiO2 or SiNx, which prevents the growth of a second buffer layer 45, rather than an Al-containing material such as AlN, AlNO, or AlO, which lowers the growth rate of the second buffer layer 45. By using this structure, as described with reference to FIGS. 21 to 23, threading dislocations may be reduced, and as shown in FIG. 25, after a support substrate or temporary substrate S is formed on the non-emitting III-nitride semiconductor stacked structure or device A, when the growth substrate 42 is removed through a process such as laser lift-off (LLO), compared to the case in which protrusions 41 formed of the same material as the growth substrate 42 are included, the growth substrate 42 can be more easily separated from the non-emitting III-nitride semiconductor stacked structure or device A. When a non-emitting device having a vertical current flow using a III-nitride semiconductor is manufactured, a shorter wavelength & higher optical flux laser beam has to be applied to a sapphire growth substrate 42 to improve the performance (particularly, breakdown voltage) and reliability of a non-emitting device (e.g., a transistor or diode) with a vertical current flow through a process of a separating and removing process (LLO process) without optical, thermal and mechanical damage and a subsequent wafer bonding process. Here, in the case in which the protrusions 41 formed of a material (Al2O3) for forming a growth substrate 42 are formed on the sapphire growth substrate 42, when a shorter wavelength & higher optical flux laser beam is applied to the backplane of the sapphire growth substrate 42 to separate in the LLO process after manufacturing the non-emitting III-nitride semiconductor stacked structure A, a large amount of laser beam scattering occurs at the boundary where the protrusions 41 are formed, making it difficult to separate the non-emitting III-nitride semiconductor stacked structure A from the sapphire growth substrate 42 due to the lack of light energy, and at the same time, allowing the scattered laser beam to extend to the non-emitting III-nitride semiconductor stacked structure A, thereby causing unexpected effects (side effects). Therefore, after separating the non-emitting III-nitride semiconductor stacked structure A from the sapphire growth substrate 42, to manufacture a high quality III-nitride semiconductor non-emitting device with a vertical current flow, the protrusions 41 are formed on the first buffer layer 43 to inhibit crystal defects including threading dislocations and minimize damage in a subsequent device manufacturing process. The protrusion base layer 71 or the first buffer layer 43 may be formed with the same composition and growth conditions as in the previous examples, and after forming a seed layer, a material layer (GaN, AlN, AlGaN, or SiNx) or a multilayer structure consisting thereof (superlattice) may be introduced to inhibit crystal defects including threading dislocations and adjust stress strain.

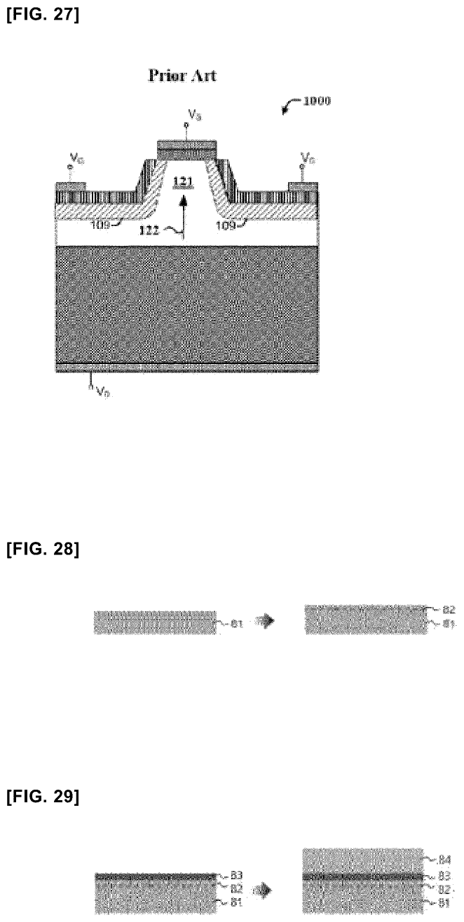

FIGS. 28 to 37 are diagrams illustrating an example of a method of manufacturing a III-nitride semiconductor stacked structure or device according to the present disclosure, and exemplify vertical junction field effect transistors, which are the same as shown in FIGS. 26 and 27, as III-nitride semiconductor stacked structures or devices.

First, as shown in FIG. 28, a buffer layer 82 is formed on a growth substrate 81. It is obvious that the method illustrated with reference to FIGS. 8 to 25 can be applied to the formation of the buffer layer 82. Compared to the devices shown in FIGS. 26 and 27, it has a difference in that a heterogeneous substrate (e.g., a Si substrate, or an Al2O3 substrate) is used, rather than a GaN growth substrate. The buffer layer 82 is preferably formed of un-doped GaN (uGaN) with a low TDD of 107/cm2 or less. The thickness of the buffer layer 82 has to be determined to minimize crystal defects (threading dislocations, vacancies, interstitial defects, substitutional defects), and its thickness is no limited as long as it is a thickness necessary to achieve this. The method and thickness described with reference to FIGS. 8 to 25 are preferentially applied.

Next, as shown in FIG. 29, a drain region 83 and a drift region 84 are formed. The drain region 83 is a region in contact with a drain electrode, which may be formed of n+GaN having a low effective electron carrier density (ND) of 1018/cm3 or more, for example, n+(Al)GaN, n++(Al)GaN, or a superlattice (AlGaN/GaN, AlInN/GaN, or GaInN/GaN). For the drain region, a thickness and doping concentration are important for forming an ohmic contact electrode, and for example, the thickness of the drain region 83 may be 1 to 100 nm.

The drift region 84 generally has a lower effective electron carrier density than the ND of the drain region 83, and as the drift region 84 is thicker, the effective electron carrier density increases. The drift region 84 is formed of, for example, n-GaN with a low ND of 1016/cm3 or less, and preferably, in the range of 2×1014/cm3 to 2×1016/cm3. The thickness of the drift region 84 may be in the range of 3 to 20 μm. It is known that as the drift region 84 is thicker, crystal defects are reduced and thus crystallinity is improved, and the threshold voltage at which a device is destroyed (i.e., the breakdown/blocking voltage) is able to be dramatically improved by distributing and releasing electric stress applied from the outside.

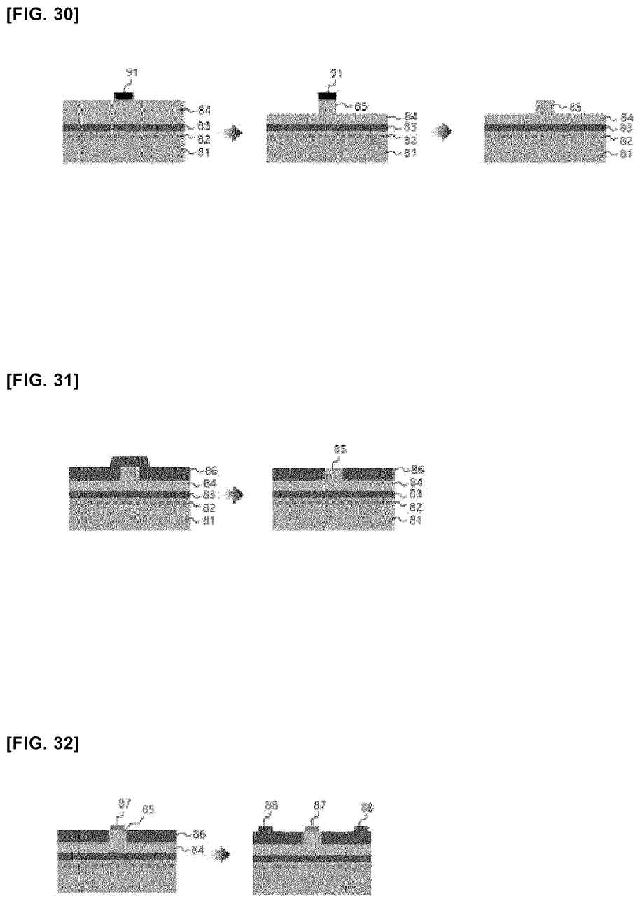

Next, as shown in FIG. 30, an etch mask 91 (e.g., a PR, a metal and/or an oxide (e.g., SiO2)) is formed on the drift region 84, and a part of the drift region 84 is removed by etching (e.g., dry etching and/or wet etching), thereby forming a channel 85. The residual etch mask 91 is removed. The height of the channel 85, which is a movement path of electron carriers with a charge (electrical mass), may be in the range of 100 to 1000 nm, and preferably, more or less 500 nm. The cross-sectional width thereof is generally 10 nm or less. A preferred shape is rectangular, but a square or circular shape is also possible.

Next, as shown in FIG. 31, a gate region 86 is formed by regrowth. In addition, to form a source electrode, the gate region 86 above the channel 85 is removed to expose the drift region 84 that forms the channel 85. The gate region 86 may be formed of, for example, p GaN, particularly, p+(Al,In)GaN or p++(Al,In)GaN. The conductivities of the gate region 86 and the drift region 84 may be changed, which is not common when a heterogeneous substrate is used. Here, n− is defined as ND≤2×1016/cm3, n,p is defined as 2×1016/cm3≤ND and NA≤2×1018/cm3, n+, pt is defined as 2×1018/cm3≤ND and NA≤2×1019/cm3, and n++, p++ is defined as 2×1019/cm3≤ND,NA. Normally, a planarization process that reduces a thin film step difference is performed by coating and curing a liquid PR material and sequentially etching a protruding part of the gate region 86 with the coated PR material by a dry etching process until the drift region 84 of the channel 85 is exposed.

Next, as shown in FIG. 32, a source electrode 87 and a gate electrode 88 are formed. The source electrode 87 is formed to make ohmic contact with the drain region 84, and the gate electrode 88 is formed to make ohmic or Schottky contact with the gate region 86. The source electrode 87 may be formed of at least two or more layers of Cr, Ti, Al, V, W. Re, TiN, CrN, Ni, Pt, and Au materials, for example, four or five layers of Cr/W/Pt/Au or Ti/Cr/W/Pt/Au. The gate electrode 88 may be formed of at least two or more layers of Pd, Ni, Pt, Ru, Rh, Cr, Ti, TiN, NiO, RuO2, and Au materials, for example, four or five layers of Pd/Ni/Pt/Au or Cr/Ni/Pt/W/Au.

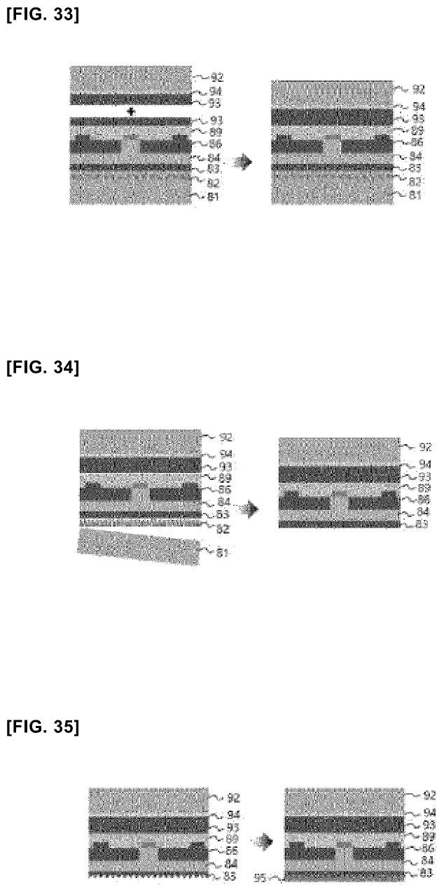

Next, as shown in FIG. 33, a passivation layer 89 serving as a protective film is formed to cover the entire top surface of a device where the source electrode 87 and the gate electrode 88 are located, and a temporary substrate 92 is attached using a junction layer 93. Subsequently, between the temporary substrate 92 and the junction layer 93, a sacrificial layer 94 for separating the temporary substrate 92 is preferably formed. The junction layer 93 may be formed on both sides or one side. The temporary substrate 92 is preferably made of the same material as the growth substrate 81, and for example, when the growth substrate 81 is a sapphire substrate, the temporary substrate 92 may also be formed of sapphire. The details of the above technology are disclosed in International Patent Laid-Open Publication Nos. WO2020/175971 and WO2021/112648.

Next, as shown in FIG. 34, after removing the growth substrate 81 (e.g., a LLO process), the buffer layer 82 is removed along with a residue generated in the process of removing the growth substrate 81 (e.g., dry etching and/or wet etching) to expose the drain region 83.

Next, as shown in FIG. 35, a drain electrode 95 is formed to make ohmic contact with the drain region 83 exposed by removing the growth substrate 81 and the buffer layer 82. A surface texture is created on the exposed drain region 83 during the removal of the buffer layer 82 to widen the area of contact with the drain electrode 95, and it is possible to perform active gas plasma treatment. The drain electrode 95 is formed over the entire exposed drain region 83. A material for the drain electrode 95 may be the same as or similar to that of the source electrode 87, and the drain electrode 95 may be formed of at least two or more layers of Cr, Ti, Al, V, W, Re, TiN, CrN, Ni, Pt, and Au materials, for example, four or five layers of Cr/W/Pt/Au or Ti/Cr/W/Pt/Au.

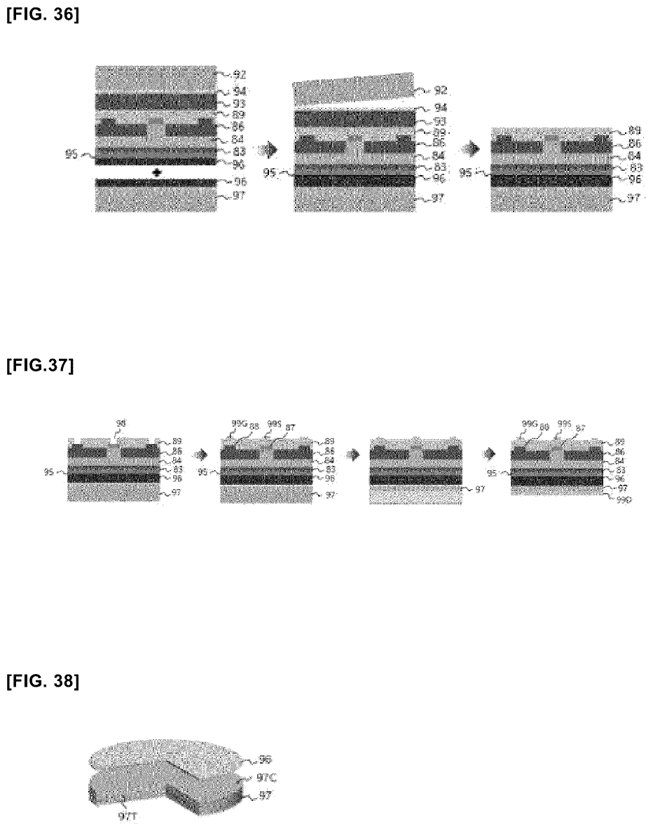

Next, as shown in FIG. 36, a support substrate 97 is attached to the drain electrode 95 via a junction layer 96. The junction layer 96 may be formed on both sides or one side. The support substrate 97 may be formed of a ceramic material (e.g., sapphire, AlN, or Si) or a composite such as CMC (Cu/Mo/Cu or Cu/MoCu/Cu) or CIC (Cu/Invar/Cu), wherein the composite is preferably a material having a difference in thermal expansion coefficient from the temporary substrate 92 of less than ±5 ppm. For example, when the temporary substrate 92 is a sapphire substrate, the support substrate 97 may be formed of sapphire. However, when the support substrate 97 is an insulating material, a vertical JFET may not be implemented, so it is necessary to form thermal and electrical paths through the support substrate 97, which will be described below. In addition to the formation of the support substrate 97 using wafer bonding, a thick film of a high heat dissipating electrically conductive metallic material (e.g., Cu or MoCu) can be deposited or plated using a high speed PVD deposition machine. Subsequently, a laser is applied to the sacrificial layer 94 to separate the temporary substrate 92, and the junction layer 93 is then removed to expose the passivation layer 89.

Next, as shown in FIG. 37, an opening 98 is formed in the passivation layer 89, a source electrode for bonding 99S and a gate electrode for bonding 99G are formed through deposition. If necessary, a drain electrode for bonding 99D is formed on the support substrate 97 through deposition. Prior to the formation of the drain electrode for bonding 99D on the support substrate 97, a process of reducing the thickness of the support substrate 97 by, for example, polishing may be added, and a vertical JFET may be completed as an example of a non-emitting III nitride stacked structure or device according to the present disclosure through the above processes.

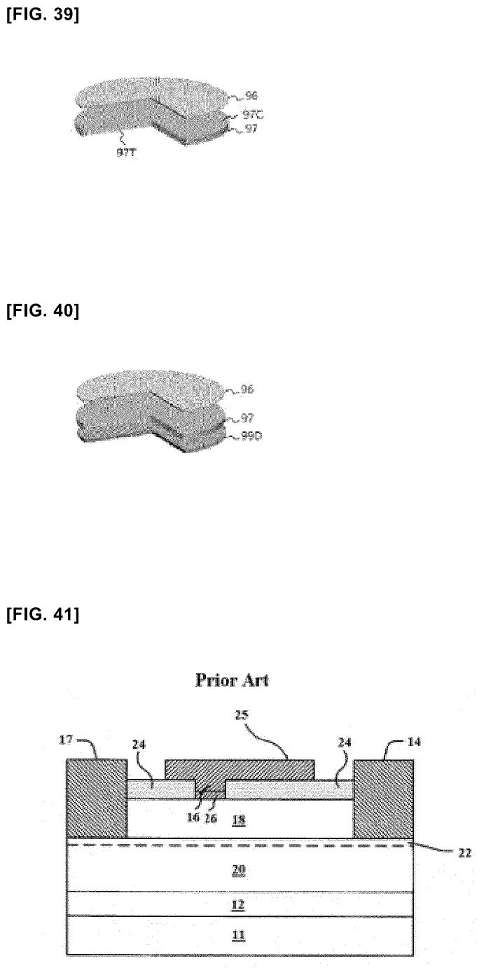

FIGS. 38 to 40 are diagrams illustrating an example of the support substrate used in the stacked structure shown in FIG. 37, wherein, as shown in FIG. 38, the support substrate 97 (e.g., a sapphire, AlN, or Si substrate) has multiple trenches or vias 97T in the top surface thereof, and the trenches or vias 97T are filled with a conductive material 97C. The conductive material 97C serves as thermal and electrical paths when the support substrate 97 is formed of an insulating material, and may serve as more improved thermal and/or electrical paths even when the support substrate 97 is formed of a conductive material. An upper layer of the junction layer 96 or support substrate is separately formed, or may be formed as part of the process of forming the conductive material 97C. Various methods for forming trenches or vias 97T and filling them with a conductive material 97C (plating, wire bonding, press-fitting, or insertion) are disclosed in International Patent laid-open publication Nos. WO2020/262957 and WO2018/106070. FIG. 39 shows that, as shown in FIG. 37, the conductive material 97C is exposed through the bottom surface by polishing the support substrate 97. Therefore, the conductive material 97C may serve as thermal and electrical paths in the support substrate 97. FIG. 40 shows that a drain electrode for bonding 99D is formed on the exposed conductive material 97C as shown in FIG. 37.

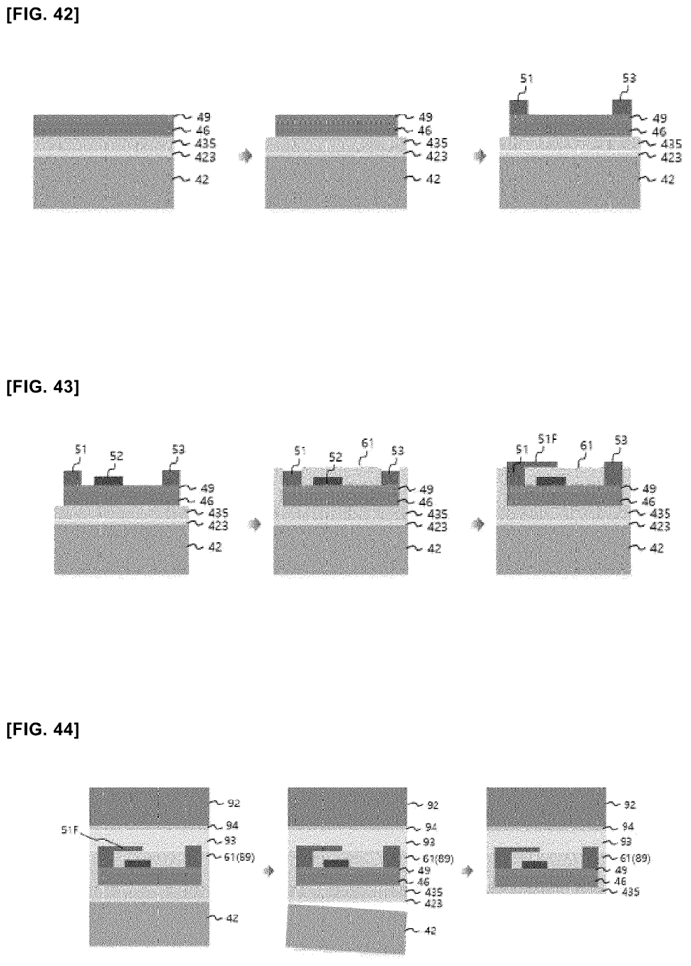

FIGS. 42 to 46 are diagrams illustrating an example of a method of manufacturing the non-emitting III-nitride semiconductor stacked structure or device shown in FIG. 41. First, as shown in FIG. 42, a seed layer 423 (e.g., AlN), a buffer layer 435, a channel layer 46 (e.g., 2-μm GaN), and a barrier layer 49 (e.g., approximately 20-nm AlGaN) are sequentially formed on a growth substrate 42 (e.g., a sapphire or Si substrate). As shown in FIG. 8, it is obvious that an interlayer 48 and a cap layer 50 may be formed, and as shown in FIG. 41, it is obvious that a III nitride layer 26 (e.g., approximately 20-nm p-type GaN) may be formed. Here, an HEMT is illustrated, but it is obvious that it can be expanded to a non-emitting III nitride device. Preferably, the buffer layer 435 may be formed by applying the method described with reference to FIGS. 8 to 25. Subsequently, the barrier layer 49 and channel layer 46 are subjected to MESA etching to expose the buffer layer 435, and then a source electrode 51 and a drain electrode 53 are formed on the top surface of the barrier layer 49. Here, it is possible to directly form the source electrode 51 and the drain electrode 53 on the top surface of the buffer layer 435 or channel layer 46 exposed to air (not shown).

Next, as shown in FIG. 43, a gate electrode 52 is formed, an insulating layer or passivation layer 61, which serves as a protective film, is formed to cover the entire top surface of the device. If necessary, a process of forming a field plate 51F by forming a required opening in the passivation layer 61 is performed. In FIG. 42, the field plate 51F is formed on the source electrode 51, but as shown in FIG. 41, it is obvious that a field plate 26 can also be formed on the gate electrode 52 and on the drain electrode 53. It is obvious that the order of forming the electrodes 51, 52, and 53 can be changed.

Next, as shown in FIG. 44, similar to that shown in FIG. 33, a temporary substrate 92 having a sacrificial layer 94 is attached to a III-nitride semiconductor stacked structure using an adhesive layer 93. Here, the passivation layer 61 serves as the passivation layer 89 of FIG. 33 in the same way. As the adhesive layer 93, an organic adhesive such as SOG, BCB, or FOx may be used. When the temporary substrate 92 is bonded to the stacked structure for a non-emitting III nitride device, and then if a subsequent process is necessary at a high temperature of 250° C.or more, a material containing a metal (Sn, In, Zn, Au, Ag, Cu, Pd, or Ni) is preferably used as the adhesive layer 93. In this case, a process of forming a gate electrode 52 and/or a field plate 51F is performed after bonding the support substrates 97 and 97a.

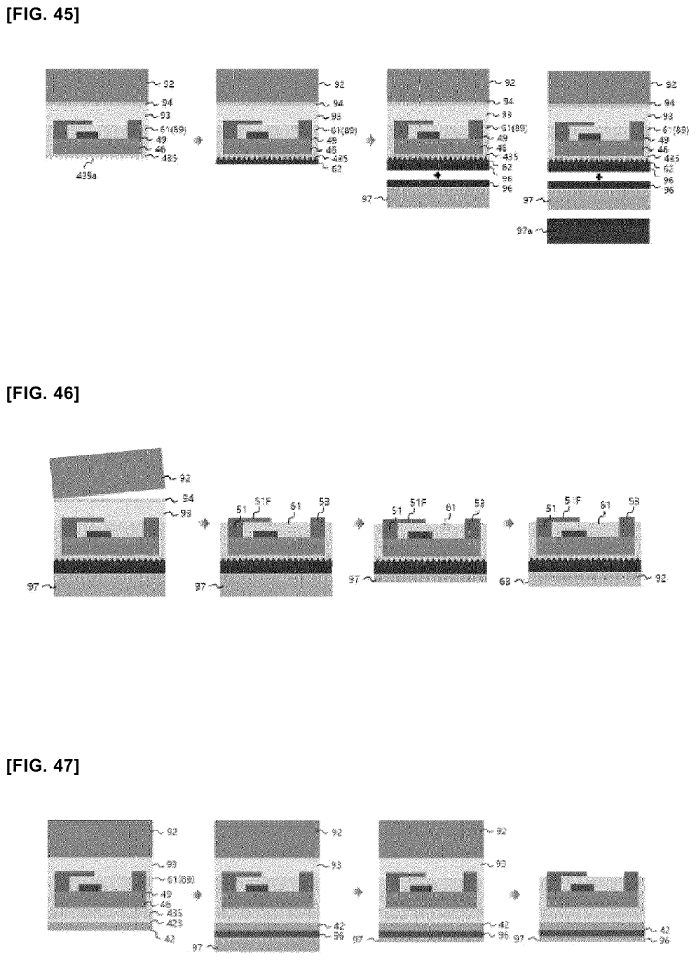

Next, as shown in FIG. 45, as in FIG. 34, a growth substrate 42 is removed (e.g., a LLO process for a sapphire substrate, and a CLO process for an Si substrate), a part of the buffer layer 435 is removed along with a residue generated during the removal of the growth substrate 42 (e.g., dry etching and/or wet etching), thereby exposing the buffer layer 435 (e.g., undoped GaN(uGaN)). Preferably, dry etching is performed until a partial surface of the N-polar uGaN is exposed, and a rough surface or surface texture 435a is formed through surface texturing to reinforce adhesive strength. It is possible to perform active gas plasma treatment. Subsequently, to prevent insulation breakdown and reinforce heat dissipation performance, a multilayer thin film 62 composed of an electrically insulating ceramic layer and a metal layer is formed. The multilayer thin film 62 includes at least a pair of ceramic/metal in the buffer layer 435, and when the multilayer thin film 62 includes n pairs of ceramic/metal, it can achieve a stress buffering function. The electrically insulating ceramic layer may be formed of, for example, AlN, BN, diamond, SiNx, or SiO2, and the metal layer may be formed of Pt, W, Ru, Rh, Mo, Cu, Cr, TiW, MoW, or CuW, which has an excellent atomic packing factor and excellent thermal conductivity. Specifically, the metal layer may be formed of N-polar GaN(buffer layer)/AlN/Pt, N-polar GaN(buffer layer)/AlN/TiW, or N-polar GaN(buffer layer)/SiNx/Pt. Subsequently, as in FIG. 36, support substrates 97 and 97a are attached to the multilayer thin film 62 using a junction layer 96. The junction layer 96 may be formed on both sides or one side. The support substrates 97 and 97a may be formed of a ceramic material (e.g., sapphire, AlN, or Si) or a composite such as CMC (Cu/Mo/Cu or Cu/MoCu/Cu) or CIC (Cu/Invar/Cu), wherein the composite is preferably a material having a difference in thermal expansion coefficient from the temporary substrate 92 of less than ±5 ppm. For example, when the temporary substrate 92 is a sapphire substrate, the support substrate may be formed of sapphire. In addition to the formation of the support substrate 97 using wafer bonding, the support substrate 97a can be formed by depositing or plating a thick film of a high heat dissipating electrically conductive metallic material (e.g., Cu or MoCu) using a high speed PVD deposition machine.

Next, as shown in FIG. 46, as in FIG. 36, when a temporary substrate 92 is removed (e.g., the LLO process for a sapphire substrate, and the CLO process for a Si substrate). Subsequently, a device is completed by removing the adhesive layer 93. When the support substrate 97 is an insulating substrate (e.g., a sapphire substrate, an AlN substrate, or a Si substrate), as shown in FIGS. 37 to 40, a support substrate 97 having a thermal path is used, its thickness is reduced by polishing, and then a bonding pad 63 is formed thereon, thereby completing a device.

FIG. 47 is a diagram illustrating an example of a method of manufacturing a non-emitting III-nitride semiconductor stacked structure or device according to the present disclosure, and has difference in that, compared to the stacked structure or device shown in FIG. 46, a growth substrate 42 is not completely removed and a part thereof remains. After completing the process shown in FIG. 43, a temporary substrate 92 is attached using a junction layer 93, and then the thickness of the growth substrate 42 is reduced by an appropriate method (e.g., mechanical polishing or ultra-precision CMP), rather than completely removing the growth substrate 42. Since sapphire or Si, which is a material that forms the growth substrate 42 has a poor heat dissipating property, the thickness of the growth substrate 42 is reduced to the minimum thickness (e.g., approximately 10 μm) required for a subsequent process. Subsequently, as in FIG. 45, a support substrate 97 is attached to the thickness-reduced growth substrate 42 using a junction layer 96. Preferably, the support substrate 97 may be formed in the method described with reference to FIGS. 38 to 40. Afterward, as shown in FIG. 46, the thickness of the support substrate 97 is reduced by polishing to expose a conductive layer 97C (see FIG. 38) through the bottom surface of the support substrate 97, and thus the conductive layer 97C effectively serves as a thermal path. Subsequently, the temporary substrate 92 is removed. If necessary, as shown in FIG. 46, it is obvious that a sacrificial layer 94 can be included. According to the process, as in FIG. 46, it is possible to first remove the temporary substrate 92.

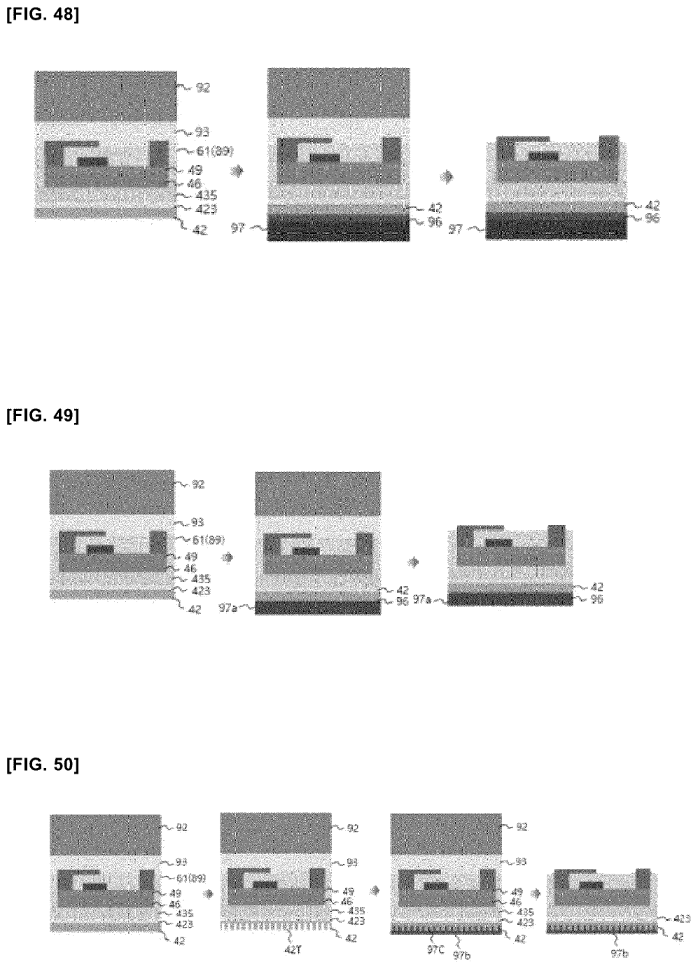

FIG. 48 is a diagram illustrating another example of a method of manufacturing a non-emitting III-nitride semiconductor stacked structure or device according to the present disclosure, and has a difference in that, compared to the stacked structure or device shown in FIG. 47, a support substrate 97 made of a ceramic material (e.g., sapphire, AlN, Si, or diamond) or a laminated composite such as CMC (Cu/Mo/Cu, Cu/MoCu/Cu), Cu/MoCu/Cu or CIC (Cu/Invar/Cu) is subjected to wafer bonding. Preferably, the composite is preferably a material having a difference in thermal expansion coefficient from the temporary substrate 92 of less than ±5 ppm.

FIG. 49 is a diagram illustrating still another example of a method of manufacturing a non-emitting III-nitride semiconductor stacked structure or device according to the present disclosure, and has a difference in that, compared to the stacked structure or device shown in FIGS. 47 and 48, a support substrate 97a is formed as a thick film by deposition of a high heat dissipating electrically conductive metallic material (e.g., Cu or MoCu) or by plating (e.g., Cu) using a high speed PVD deposition machine.

FIG. 50 is a diagram illustrating yet another example of a method of manufacturing a non-emitting III-nitride semiconductor stacked structure or device according to the present disclosure, and has a difference in that, compared to the stacked structures or devices shown in FIGS. 47 to 49, trenches or vias 42T are formed in a thickness-reduced growth substrate 42 (e.g., laser drilling), and then a support substrate 97b is formed. The trenches or vias 42T are filled with a conductive material 97C. As described above, the process of filling the trenches or vias 42T with the conductive material 97C may be performed by a method such as plating, wire bonding, press-fitting, or insertion (e.g., copper plating, copper deposition, wire bonding & stitching, or Au stud bonding & coining), which is disclosed in International Patent laid-open publication Nos. WO2020/262957 and WO2018/106070 in detail. In the example shown in FIG. 50, the support substrate 97b may be continuously or discontinuously formed, and when the support substrate 97b is formed discontinuously (e.g., in the case of wire bonding & stitching, or Au stud bonding & coining), it is possible to form it into a continuous-type support substrate 97b through additional plating or deposition.

FIG. 51 is a diagram illustrating yet another example of a method of manufacturing a non-emitting III-nitride semiconductor stacked structure or device according to the present disclosure, and has a difference in that, compared to the stacked structure or device shown in FIG. 50, the stacked structure or device shown in FIG. 51 has trenches or vias 42T that extend to a buffer layer 423, which is a nitride layer. These trenches or vias 42T may be formed by dry etching after reducing the thickness of a growth substrate 42 to approximately 20 to 30 μm. It is obvious that the trenches or vias 42T can be formed without exposing the buffer layer 423. As a conductive material 97C, which is a thermal path, extends to the buffer layer 423, which is a nitride layer, through the growth substrate 42, thermal properties are improved. However, when the trenches or vias 42T are formed deep, it is difficult to form the conductive material 97C by plating or deposition, and to address this, wire bonding & stitching and Au stud bonding & coining may be useful. It is obvious that one of the methods shown in FIGS. 47 to 49 can be added to the configurations shown in FIGS. 50 and 51. When the growth substrate 42 is completely removed as shown in FIG. 46, heat dissipation ability is enhanced, but thermal-mechanical impacts or material diffusion, which occurs during the process of removing the growth substrate 42 and forming the high heat dissipating support substrate, may adversely affect the long-term reliability of the device. Therefore, the long-term reliability of the device may be ensured without significantly restraining the heat dissipation ability by using a growth substrate 42 with a thickness reduced to approximately 10 μm. However, while further ensuring the long-term reliability of the device using a growth substrate 42 with a thickness reduced to approximately 20 to 30 μm, the heat dissipation ability can also be improved by forming the trenches or vias 42T to create thermal paths using the conductive material 97C.

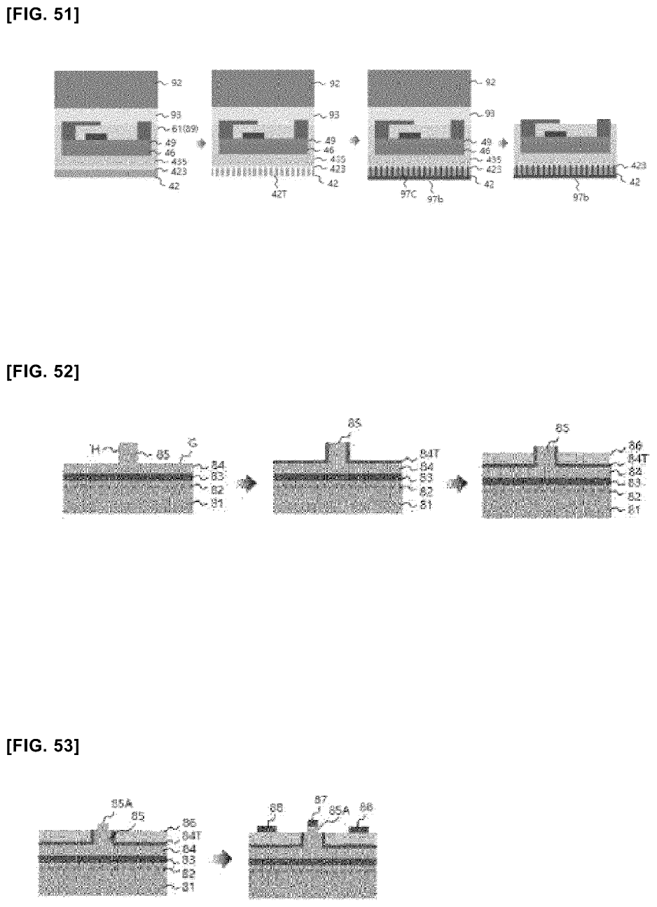

FIGS. 52 and 53 are diagrams illustrating yet another example of the method of manufacturing a III-nitride semiconductor stacked structure or device according to the present disclosure, and illustrates a method of manufacturing vertical JFET, which is the same as shown in FIGS. 26 and 27. This method is overall the same as the method described with reference to FIGS. 28 to 37, but there are differences in the process and form shown in FIGS. 30 to 32.

As shown in FIGS. 30 and 31, a channel 85 is formed by removing a part of a drift region 84, and a gate region 86 has to be formed through regrowth. However, here, the gate region 86 (e.g., p-type GaN) is created at both contact sides corresponding to sides exposed by etching of the bottom surface G (see FIG. 52), which is the c-face of the drift region 84 (e.g., n-type GaN) and a side surface H (drift region 84) of the channel 85, which is an m-face or an a-face. These two contact sides become regions where leakage current is generated during the operation of the device.

To prevent this, first, as shown in FIG. 52, after forming a buffer layer 82, a drain region 83, a drift region 84, and a channel 85 on a growth substrate 81 through the process shown in FIG. 30, an interlayer 84T is introduced without immediate regrowth of a gate region 86. As described above, the gate region 86 may consist of p GaN, p+(Al,In)GaN, or p++(Al,In)GaN. The interlayer 84T may be formed of (Al, In)GaN or n-type (Al,In)GaN, which is not doped, or AlN by the same method (e.g., MOCVD) as used for the drift region 84, or AlN or AlNO using sputtering. In addition, the interlayer 84T may be formed as a multilayer consisting of two or more layers of (Ala,Inb)GacN/(Alx,Iny)GazN, or as a widely known superlattice structure. It is obvious that an n-type dopant (Si or Ge) may be injected into the multilayer and superlattice structures. The structure that introduces the interlayer 84T between the drift region 84 and the gate region 86 may be designed identical or similar to the n−/i/p++ diode structure to serve as a depletion layer in the vertical or horizontal direction at the bottom surface G and the side surface H, which are the contact sides, performing a rectifying function. Accordingly, the thickness of the interlayer 84T that has the same role as “i” is not limited as long as it can reinforce the rectifying function. Preferentially, the thickness is 50 nm or less, and leakage current may be reduced by introducing the interlayer 84T with this function. After removing a part of the n− semiconductor drift region 84 through an etching process, it would be ideal that the rectifying function is completed by means of an n−/p++ diode structure through the regrowth of the gate region 86 of the p++ semiconductor, but the possibility of leakage current caused by the surface damage to the drift region 84 is increased by etching a part of the n− semiconductor drift region 84 and continuously regrowing the gate region 86 of the p++ semiconductor. To improve this, the interlayer 84T is preferably introduced. While the interlayer 84T is illustrated as not covering the top of the channel 85, it is obvious that the interlayer 84T can be formed on the upper part of the channel 85.

Next, as shown in FIG. 31, a gate region 86 is formed. It is obvious that the gate region 86 can be formed to cover the upper part of the channel 85.

Next, as shown in FIG. 53, as shown in FIG. 31, a planarization process is performed to reduce the step difference between the channel 85 and the gate region 86. Here, side surfaces of the upper part 85A of the channel 85 may be exposed by removing the interlayer 84T. When the upper part 85A remains, the thickness of the drift region 84 increases, so it is expected to reinforce a breakdown voltage due to the electrical field distribution. On the other hand, since energy loss may further increase due to the increase in electrical resistance during operation, the device has to be designed by considering these factors.

Subsequently, as shown in FIG. 32, a source electrode 87 and a gate electrode 88 are formed.

Referring again to FIGS. 8 to 23, in the process of forming the growth prevention films 44, it is not easy to align the growth prevention films 44 on the upper part of the protrusions 41 (one example of the alignment is shown in FIG. 9). Particularly, conventionally, for alignment with the upper part of the protrusion 41, an aligned pattern process is performed using a photolithography process, which is complicated, so it has the disadvantage of reducing a defect reducing effect and significantly increasing production costs.

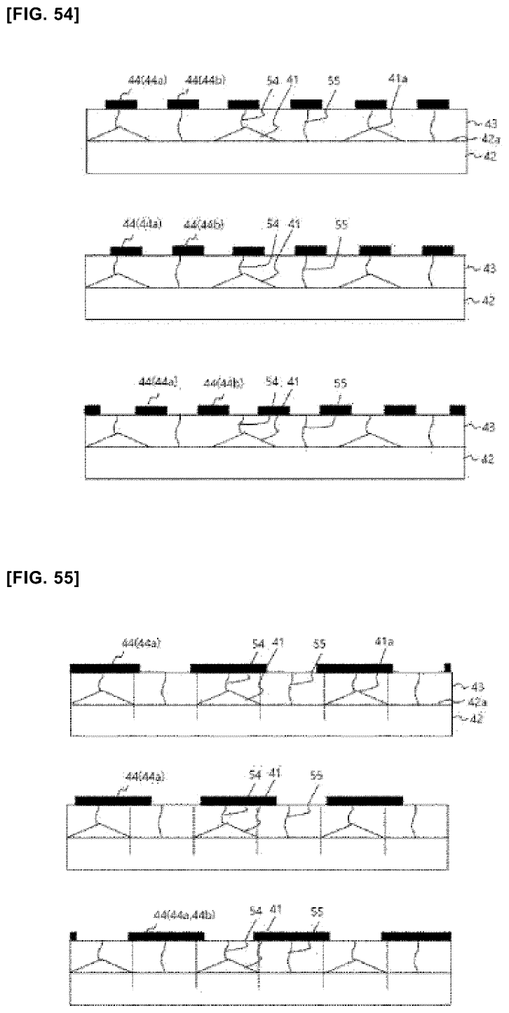

FIGS. 54 and 55 are diagrams illustrating other examples of the arrangement relationship between the protrusions and the growth prevention films according to the present disclosure. To help understanding, as shown in FIG. 54, as shown in one dimension (described based on the longitudinal sectional view), when the growth prevention films 44 are not aligned with the protrusions 41, there may be no effect of reducing defects (threading dislocations) located on the upper part or top surface 41a of the protrusions 41 by the growth prevention films 44.

That is, as shown in the top view of FIG. 54, when the growth prevention films 44 and the protrusions 41 are precisely aligned, threading dislocations 54 located on the upper part or top surface 41a of the protrusions 41 and threading dislocations 55 located on the bottom surface of the growth substrate 42 or the bottom surface 42a of the protrusions 41 may be blocked by the growth prevention films 44, specifically, a growth prevention film 44a and a growth prevention film 45b.

In the middle view of FIG. 54, the growth prevention films 44 are shown slightly misaligned with the protrusions 41, and the threading dislocations 54 and 55 are still blocked by the growth prevention films 44a and 44b.

In the bottom view of FIG. 54, the growth prevention films 44 are shown completely misaligned with the protrusions 41, and in this case, the growth prevention films 44a and 44b do not function to block the threading dislocations 54 and 55 and simply serve to improve film quality to a certain extent by enabling ELOG of a second buffer layer 45 (see FIG. 8) grown thereon.

In FIG. 55, a growth prevention film 44 (44a) wider than the width of a protrusion 41 (the width of a protrusion 41 on the bottom surface 42a). In the top view of FIG. 55, the growth prevention films 44a are aligned with the protrusions 41, and threading dislocations 54 are blocked by the growth prevention films 44a to improve film quality during the subsequent growth process. In the middle view of FIG. 55, the growth prevention films 44a are shown slightly misaligned with the protrusions 41, and the threading dislocations 54 are still blocked by the growth prevention films 44a. In the bottom view of FIG. 54, the growth prevention films 44a are shown misaligned with the protrusions 41 to the maximum extent. Here, the growth prevention film 44a does not block the threading dislocation 54, but blocks the threading dislocation 55, which means it functions as a growth prevention film 44b, and the threading dislocation 55 is blocked by the growth prevention film 44b to improve film quality during the subsequent growth process.

In summary, it can be seen that, by designing growth prevention films 44 with a specific scale, the growth prevention films 44 can block at least a part of the threading dislocations 54 and 55 present in the first buffer layer 43 regardless of the alignment with the protrusions 41.

FIGS. 54 and 55 illustrate the case where the width of the protrusions 41 and the interval between the protrusions 41 are the same. However, when the width of the protrusions 41 is larger than the interval between the protrusions 41, the length of the growth prevention films 44 may be designed to be the same as or larger than the width of the protrusions 41, thereby blocking a part of the threading dislocations 54 and 55 regardless of the alignment with the protrusions 41, and when the width of the protrusions 41 is smaller than the interval between the protrusions 41, the length of the growth prevention films 44 is designed to be the same as or larger than the interval between the protrusions 41, thereby blocking a part of the threading dislocations 54 and 55 regardless of the alignment with the protrusions 41. That is, considering the size and arrangement of the protrusions 41 on the growth substrate 42, when the growth prevention films 44 are well designed, it can be seen that the threading dislocations 54 and 55 may be blocked to a desired level regardless of the alignment with the protrusions 41. Although it is possible to consider designing the growth prevention films 44 to be unlimitedly large, the upper limit of the size of the growth prevention films 44 should not be limited by considering the growth region of a second buffer layer 45.

In the above, for better understanding, the size and arrangement of the growth prevention films 44 have been described one-dimensionally (based on the longitudinal sectional view), but the actual growth prevention films 44 have to be described two-dimensionally (based on a plan view) as shown in FIG. 9 (misalignment in both the x axis and y axis directions should be considered), and therefore, the previously described concept of length can be explained by the concept of region. That is, the case in which the length of the growth prevention film 44a located on the protrusions 41 is designed to be the same as or larger than the width of the protrusion 41 is replaced with the case in which the area of the growth prevention film 44a located on the protrusions 41 is designed to be the same as or larger than the area of the protrusion 41 (the area of the protrusion 41 on the bottom surface 42a). The case in which the length of the growth prevention film 44b located on the bottom surface 42a of the growth substrate 42 is designed to be the same as or larger than the interval between the protrusions 41 may be replaced with the case in which the area of the growth prevention film 44b is designed to be larger than the area of a circle whose diameter is the interval between the protrusions 41 (a different shape other than a circle can be considered). As described above, the interval between the growth prevention films 44a and 44b whose areas are designed as above (i.e., the upper limit and shape of the growth prevention films 44a and 44b) may be determined from the perspective of securing the growth area of the second buffer layer 45. Generally, in the case of microscale protrusions 41 with a width of 1 μm or more, they have a width of 1 to 2.5 μm and an interval of 0.4 μm or less, and in the case of nanoscale protrusions 41 with a width of less than 1 μm, they have a width of 500 nm or less and an interval of 50 nm or less, so the area of the growth prevention film 44a has to be designed according to the width and shape of the protrusions 41. The size of the growth prevention films may be defined in terms of horizonal and vertical widths instead of an area, one of the horizontal and vertical widths may be the same as or larger than the size and/or interval of the protrusions, and preferably, both of the horizontal and vertical widths are the same as or larger than the size and/or interval of the protrusions.

Looking at this problem from a different perspective from the above, for example, TDD, since the target TDD is 107/cm2 or less, assuming that the TDD after the growth of the first buffer layer 43 is, for example, 108/cm2 (in reality, it will be higher than this), a TDD of 108/cm2 means that there are 100,000,000 (=108) threading dislocations 54 and 55 in an area (width*length) of 1 cm*1 cm (=107 nm*107 nm), and it can be statistically shown that there is one threading dislocation 54 or 55 in an area (width*length) of 103 nm*103 nm (1 μm*1 μm). That is, when the TDD of the first buffer layer 43 is 108/cm2, assuming that the threading dislocations 54 and 55 are uniformly distributed, there is one threading dislocation 54 or 55 in an area (width*length) of 103 nm*103 nm (1 μm*1 μm) (hereinafter, referred to as a unit area). When the TDD of the first buffer layer 43 is 109/cm2, it can be understood that there is one threading dislocation 54 or 55 in a unit area of (width*length) of 316 nm*316 nm (0.316 μm*0.316 μm). Accordingly, when the TDD of the first buffer layer 43 is 109/cm2 or more, by forming a pattern (a circle, hexagon, diamond, quadrangle, or stripe, etc.) with a width or diameter of 0.3 μm, it can be seen that the threading dislocations 54 and 55 can be reduced to a desired level or less without aligning the protrusions 41 and the growth prevention films 44.

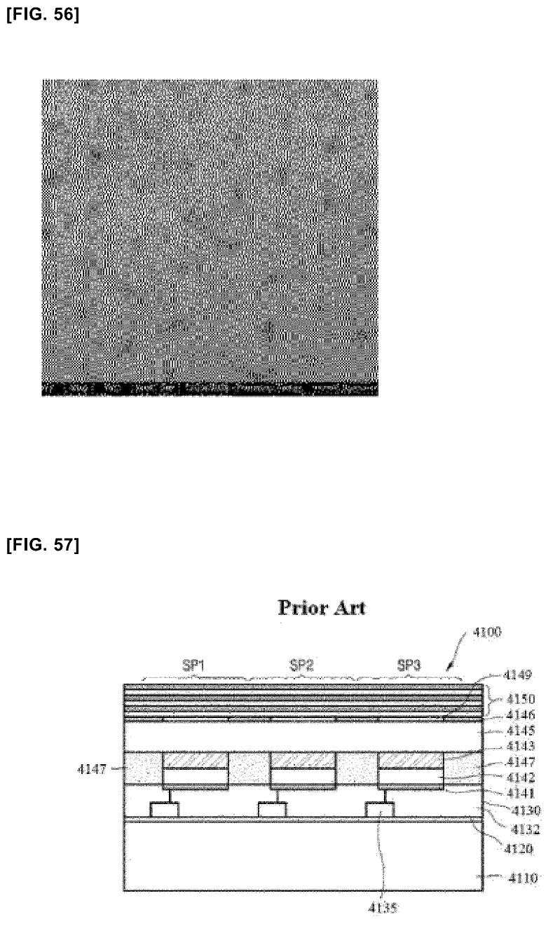

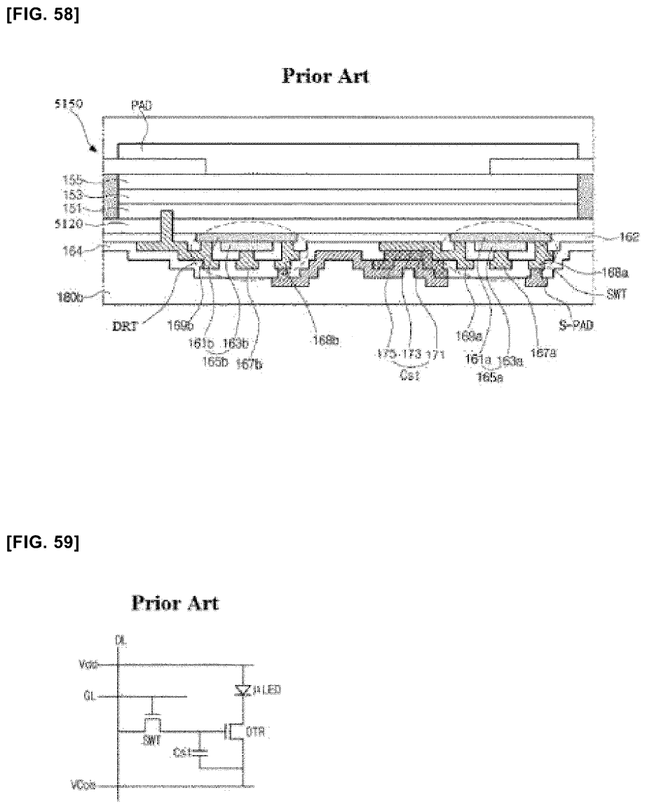

FIG. 56 shows an example of a monochromatic CL image illustrating crystal defects formed in a first buffer layer, in which black dots represent threading dislocations (in particular, indicating screw-type threading dislocations (TDs)), and linear crystal defects that link the black dots refer to mixed threading dislocations (TDs) including screw-type TDs (threading dislocations in which edge-type TDs and screw-type TDs are combined). Threading dislocations 54 formed on the upper part or top surface of protrusions 41 (see FIG. 54) correspond to screw-type TDs of the black dots. For reference, among TDs generated from the bottom surface 42a (see FIG. 55) of the growth substrate 42, most of the TDs are edge-type TDs, and the reason why they do not appear independent, that is, in a connected shape, not a dot shape, on the CL image is that TDs generated from the growth substrate 42 are slanted at an oblique angle, interact with other neighboring TDs, and then continue in the growth direction. Accordingly, after forming a first buffer layer 43 (see FIG. 54), it is possible to determine the size (horizontal width and vertical width) of the growth prevention film 44 by considering the density of or average distance between TDs (e.g., average distance between screw-type TDs) in the first buffer layer 43. Preferably, by designing one of the horizontal width and vertical width of the growth prevention film 44 to be the same as or longer than the average distance between TDs, even when the growth prevention films 44 and the protrusions 41 are not aligned, it is possible to reduce TDs to a required level. For example, since microscale protrusions 41 with a width of 1 μm or more have a width of 1 to 2.5 μm and an interval of 0.4 μm or less, and nanoscale protrusions 41 with a width of less than 1 μm have a width of 500 nm or less and an interval of 50 nm or less, the area of the growth prevention films 44 is designed according to the width, interval, and shape of the protrusions 41. Although the edge-type TDs are not only crystal defects, since they may be necessary in terms of releasing the stress of the semiconductor stacked structure, when the edge-type TDs need to be reduced to a certain level or lower, they can be reduced by forming an SiNx nano mask prior to the formation of the growth prevention films 44 (as the final step of growing the first buffer layer 43) (refer to Improving Transport Properties of GaN-Based HEMT on Si(111) by Controlling SiH4 Flow Rate of the SiNx Nano-Mask, MDPI, Published on 25 Dec. 2020).

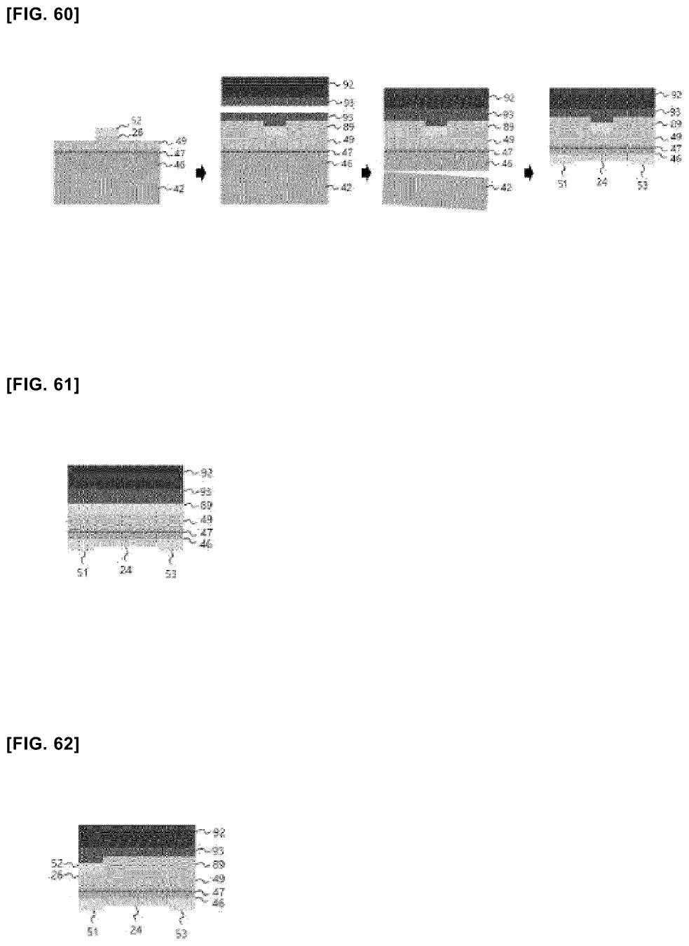

FIG. 60 is a diagram illustrating yet another example of a method of manufacturing a non-emitting III-nitride semiconductor stacked structure or device according to the present disclosure. First, a channel layer 46, a 2DEG 47, a barrier layer 49, and a gate electrode 52 are formed on the growth substrate 42. As a III nitride layer 26 (see FIG. 41) is included, it is possible to implement the device in a normally-off state. It is obvious that the first buffer layer 43, the growth prevention films 44, the second buffer layer 45, the interlayer 48, and/or the cap layer 50 may be included (see FIG. 8).

Subsequently, as shown in FIG. 33, after forming a passivation layer 89 serving as a protective film, a temporary substrate 92 is attached using a junction layer 93. Preferably, between the temporary substrate 92 and the junction layer 93, a sacrificial layer 94 is included to separate the temporary substrate 92. The junction layer 93 may be provided at both sides or one side. As the temporary substrate 92, a transparent material that makes it relatively easy to separate (lift off) the temporary substrate 92 in a subsequent process, is able to be processed at low cost, and is suitable for a laser lift-off (LLO) process that can use a laser beam is used without particular limitation. Of course, chemical lift-off (CLO) or a process combining chemical etching and mechanical polishing (chemical-mechanical polishing; CMP) is possible. Particularly, for the LLO process, the temporary substrate 92 made of a transparent material may include glass, sapphire, or quartz. When the temporary substrate 92 is formed of a non-transparent material such as a metal or Si, it is possible to remove the temporary substrate 92 through wet etching and/or mechanical polishing. As shown above, after forming the passivation layer 89 to completely cover the gate electrode 52, the gate electrode 52 may be exposed. It is preferable to minimize the height difference between the passivation layer 89 and the gate electrode 52, and even when there is a height difference, planarization is possible by reducing the height difference using the junction layer 93 in the subsequent wafer bonding process.

Subsequently, as shown in FIG. 34, the seed layer and the buffer layer, which are introduced for film formation of a non-emitting III-nitride semiconductor stacked structure, are completely removed by removing the growth substrate 42 (e.g., the LLO process), and the channel layer 46 is exposed.

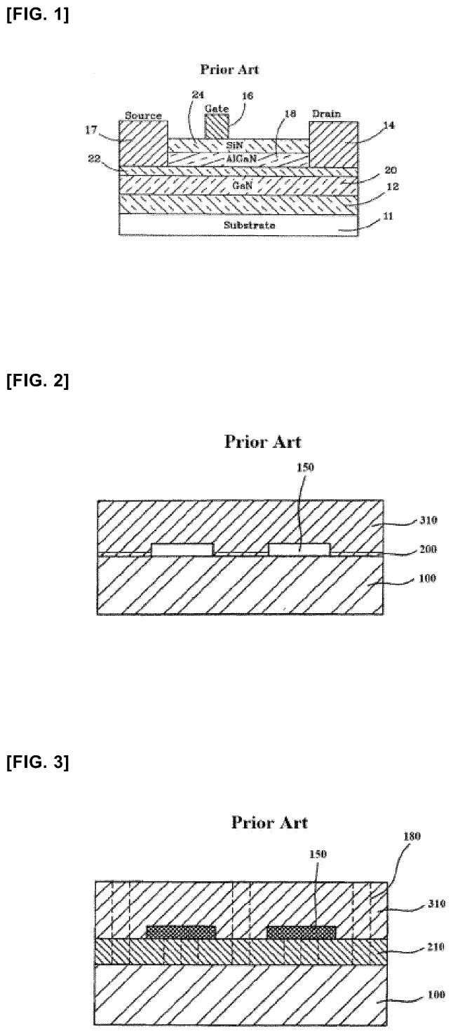

Finally, a source electrode 51 and a drain electrode 53 are formed on the channel layer 46. Preferably, as shown in FIGS. 1 and 41, before or after forming the source electrode 51 and the drain electrode 53, an insulating layer 24 (SiN insulating layer) is formed. The source electrode 51 and the drain electrode 53 are formed on the channel layer 46, which is exposed by removing the growth substrate 42. Here, since the exposed channel layer 46 becomes a nitrogen (N) polarity surface, it is easy to form a non-alloyed ohmic contact, and it is possible to form an alloyed ohmic contact at a relatively lower temperature. Meanwhile, since the barrier layer 49 on which the gate electrode 52 is formed is a metallic (Ga, Al) polarity surface, which is a surface in its original state of growth, it is easy to form the gate electrode 52 using a Schottky or ohmic contact. In addition, to form the source electrode 51 and the drain electrode 53 to have ohmic contact characteristics with low contact resistance, prior to the deposition of two electrode materials, a plasma treatment or surface texturing process may be introduced to the nitrogen polarity surface.

FIGS. 61 and 62 are diagrams illustrating various forms of the non-emitting III-nitride semiconductor stacked structure or device manufactured according to the method shown in FIG. 60, and in FIG. 61, the gate electrode 52 is formed over the entire stacked structure or device, and the passivation layer 89 is omitted. Due to this configuration, current leakage may be reduced. In FIG. 62, the gate electrode 52 is located close to the source electrode 51, and by reducing the distance between the gate electrode 52 and the source electrode 51, the size of the device may be reduced, thereby minimizing a parasitic effect and reducing electrical resistance and parasitic capacitance during high-speed switching operation.

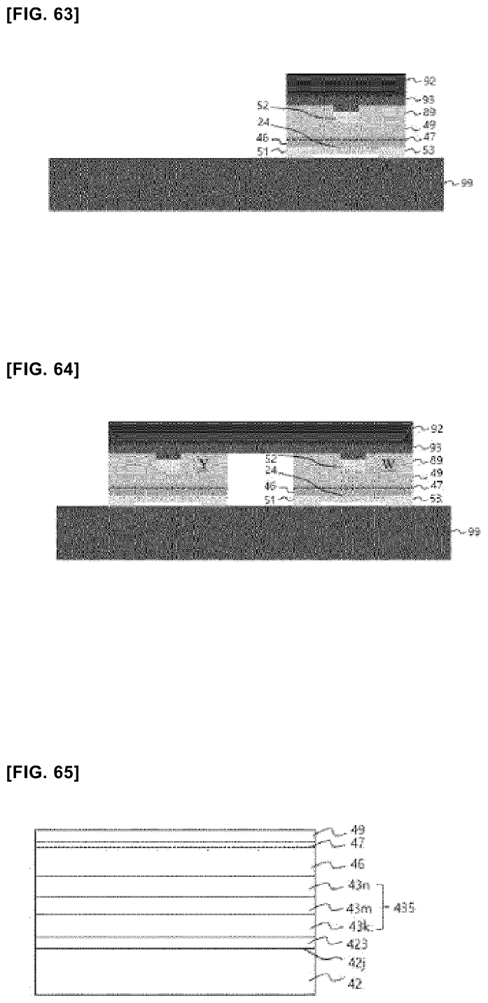

FIG. 63 is a diagram illustrating an example of a method of transferring the non-emitting III-nitride semiconductor stacked structure or device manufactured according to the method shown in FIG. 60, wherein the stacked structure or device (W) is placed on a support substrate 99. When the stacked structure or device is individualized, it may be transferred onto the support substrate 99 by a pick & place method. When the support substrate 99 is a support substrate 4110 described with reference to FIG. 57 (e.g., a wiring board, or a backplane board), the source electrode 51 and the drain electrode 53 may be attached to the support substrate 99. As described above, when the temporary substrate 92 and the junction layer 93 are formed of conductive materials, it is possible to supply current to the gate electrode 52, so they can be left as they are, and when the temporary substrate 92 and/or the junction layer 93 are formed of non-conductive materials, the temporary substrate 92 may be removed. As described above, when the temporary substrate 92 is a transparent substrate, by using the configuration and method (LLO process) shown in FIG. 36, it is possible to remove the temporary substrate 92 while minimizing the damage to the support substrate 99, and if necessary, it is possible to remove the junction layer 93 or a contact layer/passivation layer 93 and expose the gate electrode 52. It is obvious that even when the temporary substrate 92 is formed of a conductive material, it can be removed.

FIG. 64 is a diagram illustrating another example of the method of transferring the non-emitting III-nitride semiconductor stacked structure or device manufactured according to the method shown in FIG. 60, and a plurality of stacked structures or devices (W and Y) of the temporary substrate 92 are transferred to the support substrate 99 while being included. Here, since a junction layer 93 is not included on the temporary substrate 92, the junction layer 93 may be omitted between the plurality of stacked structures or devices (W and Y). The arrangement of the plurality of stacked structures or devices (W and Y) placed on the temporary substrate 92 is made possible by performing photolithography & etching processes on a stacked structure or device in a wafer state, or transferring the stacked structures or devices (W and Y), which are already individualized, onto the temporary substrate 92 by a pick & place method. A specific form of arrangement may vary depending on the interconnection type of the support substrate 99, and when the plurality of stacked structures or devices (W and Y) correspond to subpixels in one pixel, a solution that can perform transfer while reducing minor errors is provided. The method of removing the temporary substrate 92 has already been described in the example shown in FIG. 63.

FIG. 65 is a diagram illustrating still another example of the non-emitting III-nitride semiconductor stacked structure or device according to the present disclosure, wherein the non-emitting III-nitride semiconductor stacked structure or device (e.g., HEMT) includes a growth substrate 42, a seed layer 423, a buffer layer 435, a channel layer 46 (e.g., 2-μm GaN), and a barrier layer 49 (e.g., 20-nm AlGaN). Preferably, it is obvious that the non-emitting III-nitride semiconductor stacked structure or device can include a pre-seeding layer 42j (formed by providing a TMAl gas as an aluminum (Al) source alone without the supply of an ammonia (NH3) gas as a nitrogen (N) source), an interlayer 48 (see FIG. 8), and/or a cap layer 50, and as shown in FIG. 41, a III nitride layer 26 (20-nm p-type GaN) can be included. When a Si substrate is used as the growth substrate 42, the seed layer 423 may consist of AlN to prevent a reaction with GaN present in an upper layer, the seed layer 423 formed of AlN may be formed to a thickness of 50 nm or less at a low temperature (500 to 900° C.). The buffer layer 435 may include a first layer 43m (AlaGa1−aN (0≤a≤1)) and a second layer 43n (AlbGa1−bN (0≤b<1)), wherein the first layer 43m serves as a strain control layer (corresponding to the first layer in FIG. 12) which addresses the difference in lattice constant between the seed layer 423 made of AlN and the layers (the second layer 43n and the channel layer 46) made of GaN located above, and the second layer 43n corresponds to the second layer in FIG. 12 and the second buffer layer 45 in FIG. 17. Preferably, the buffer layer 435 is grown at a high temperature (1000° C. or more) to enhance the crystallinity of itself (43m and 43n) and the III nitride stacked structures 46, 47, and 49, which are located above the layers 43m and 43n, and includes an AlN layer 43k with a thickness of 1 μm or more.

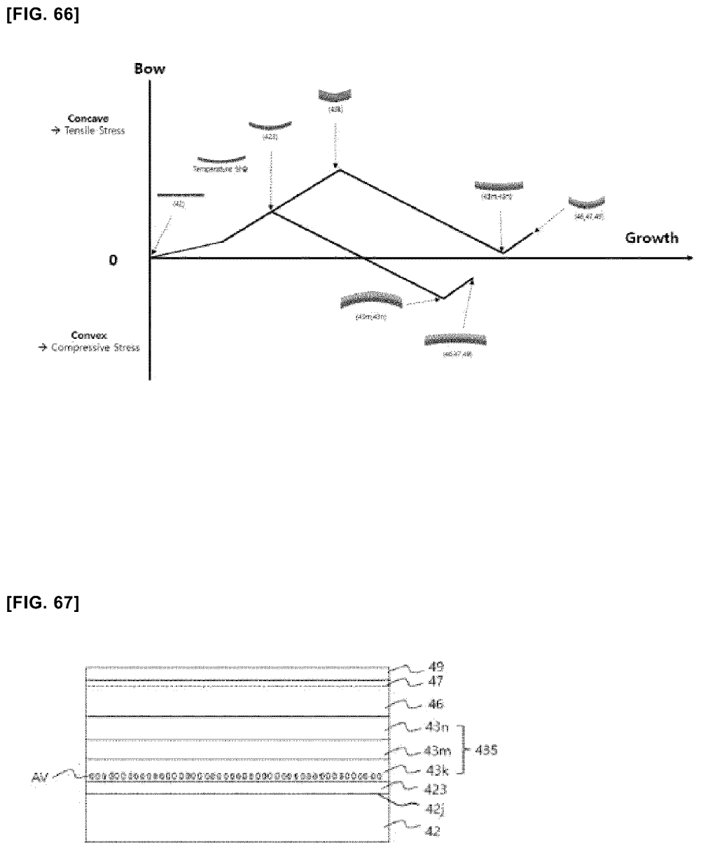

FIG. 66 is a diagram illustrating wafer bowing during the growth of the non-emitting III-nitride semiconductor stacked structure or device shown in FIG. 65.

First, the bowing behavior of a wafer that is grown at a high temperature (HT) and does not include the AlN layer 43k is examined. The growth substrate 42 is flat before growth and becomes maximally concave while the seed layer 423 that is grown at a low temperature (LT) and formed of AlN is grown on the growth substrate 42. This is due to the difference in lattice constant and thermal expansion coefficient between the Si growth substrate 42 and the AlN, and when excessively bowed, that is, when tensile stress increases to a certain extent or more, cracks are generated in the AlN epitaxial layer and the wafer. When the first layer 43m (AlaGa1−aN (0≤a≤1)) with a gradually increasing GaN component ratio (1−a) and the second layer 43n (AlbGa1−bN (0≤b<1)) with a high GaN component ratio (b−1) are grown on the wafer, the wafer changes from a concave state to a convex state, and no cracks occur in a state of compressive stress. Subsequently, when the channel layer 46 (e.g., GaN), a 2DEG 47, and the barrier layer 49 (e.g., AlGaN) are grown, the degree of concavity/convexity is reduced, but the growth is completed in a concave state without cracks. For reference, in terms of device behavior, the second layer 43n and the channel layer 46 are distinguished, but in terms of device manufacture, these layers may become one layer consisting of GaN without aluminum (Al).

Next, the bowing behavior of the wafer including the high temperature (HT)-grown AlN layer 43k is examined. Before growth, the growth substrate 42 is flat, and becomes maximally concave while the low temperature (LT)-grown AlN seed layer 423 and the HT-grown AlN layer 43k are grown on the growth substrate 42. Since at least a 1-μm AlN layer 43k is grown as well as the seed layer 423, the concavity of the wafer becomes much greater, and the risk of wafer cracks becomes much greater. Subsequently, when the first layer 43m and the second layer 43n are grown, the concavity decreases, but as shown in FIG. 66, the wafer may not be flat or in a convex state, and when the channel layer 46 (e.g., GaN), the 2DEG 47, and the barrier layer 49 (e.g., AlGaN) are further grown, the concavity increases again, so the possibility of wafer cracks increases. To reduce the risk of such cracks, it is necessary to adjust growth conditions so that the final finished wafer is flat or convex.

FIG. 67 is a diagram illustrating yet another example of a non-emitting III-nitride semiconductor stacked structure or device according to the present disclosure, and has a difference in that there are air voids AV in an HT-grown AlN layer 43k compared to the stacked structure or device shown in FIG. 65. Due to the air voids AV, tensile stress may be released, the crystallinity of the HT-grown AlN layer 43k grown above the air voids AV may be enhanced, and layers 43m, 43n, 46, 47, and 49, which are grown above, may be improved (refer to Effectively releasing tensile stress in AlN thick film for low-defect-density AlN/sapphire template; 24 Jul. 2020; Semiconductor Today). The HT-grown AlN layer 43k with air voids AV has two main roles: \textcircled{1} During the growth of an AlN thin film at a high temperature of 100° C. or more, rapidly increased tensile stress (concave form of wafer) is released to inhibit cracking in a subsequently grown non-emitting III-nitride semiconductor stacked structure or Si wafer; and \textcircled{2} air voids AV introduced in the HT AlN thin film dramatically reduce a misfit dislocation (threading dislocation) density by filtering crystal defects, particularly, misfit or threading dislocations, generated from a Si growth substrate 42, or a pre-seeding layer 42j or seed layer 423.

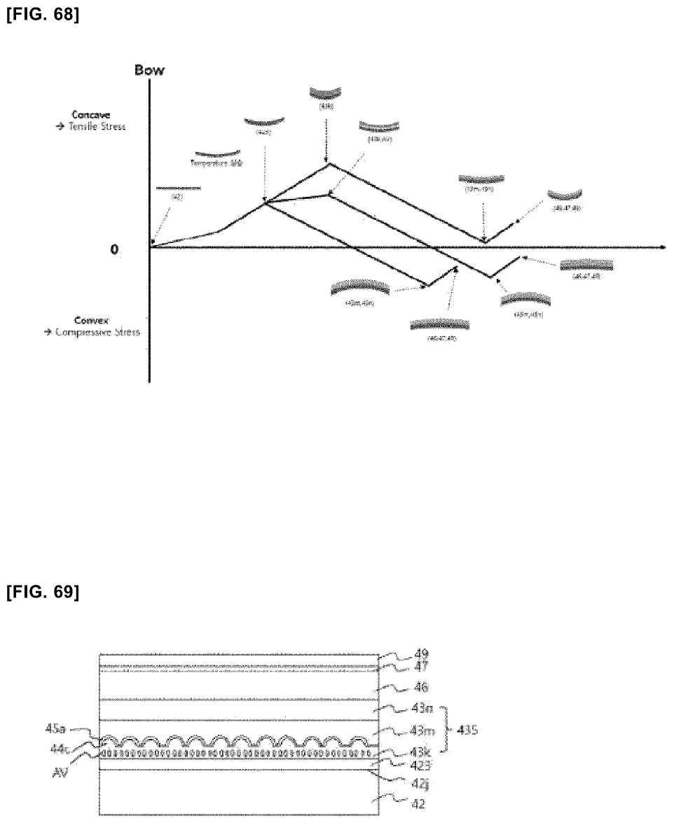

FIG. 68 is a diagram illustrating wafer bowing during the growth of the non-emitting III-nitride semiconductor stacked structure or device shown in FIG. 67. It can be seen that the HT-grown AlN layer 43k with air voids AV has a smaller degree of maximum concavity compared to the HT-grown AlN layer 43k without air voids AV and thus the final wafer may be formed in a convex shape.

FIG. 69 is a diagram illustrating yet another example of a non-emitting III-nitride semiconductor stacked structure or device according to the present disclosure, in which protrusions 44c as shown in FIG. 18 are further included in the HT-grown AlN layer 43k in the stacked structure or device shown in FIG. 67. As described above, the addition of the protrusions 44c brings improvement in film quality to the stacked structure or device. Here, it is important to ensure that the air voids AV are not exposed to the upper part of the protrusions 44c, and to this end, the air voids AV may be formed at the bottom of the HT-grown AlN layer 43k, or the HT-grown AlN layer 43k may be formed sufficiently thick. The air voids AV may be formed by growing the HT-grown AlN layer 43k at a medium temperature (MT) (900 to 1000° C.) between the growth temperature of the HT-grown AlN layer 43k (1000° C. or more) and the growth temperature of the LT-grown AlN seed layer 423 (500 to 900° C.) (refer to Effectively releasing tensile stress in AlN thick film for low-defect-density AlN/sapphire template; 24 Jul. 2020; Semiconductor Today). Accordingly, a location where the air voids AV are formed in the HT-grown AlN layer 43k may be adjusted by adjusting growth conditions. Preferably, as shown in FIG. 21, a material layer 45a (e.g., PVD AlN, or PVD AlNO) may be introduced. The air voids AV may have various shapes such as a serrated shape, a circular shape, a cobbled shape, and a nail shape, and for example, the air voids AV may be formed such that the region grown at a middle temperature (MT) occupies approximately ¼ to ⅓ of the entire AlN layer 43k.

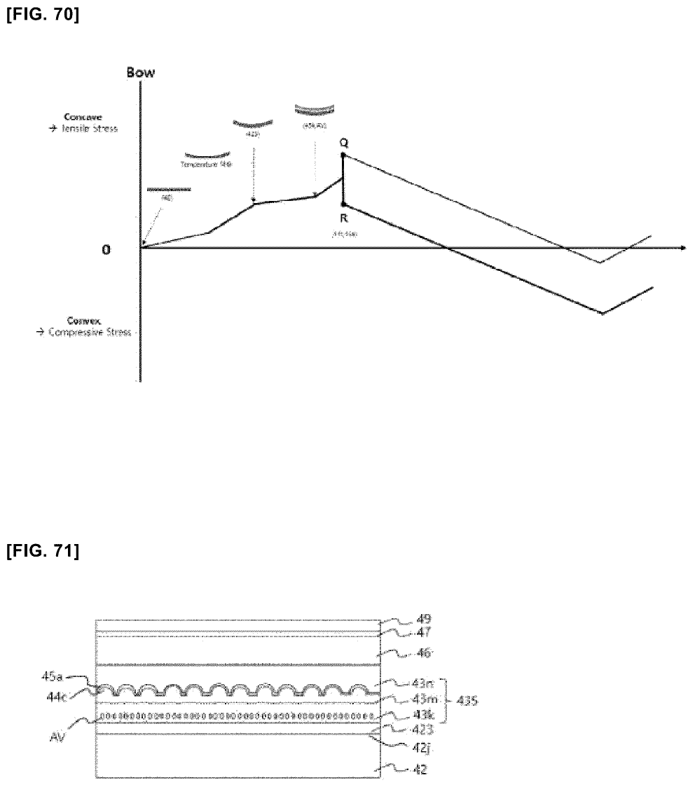

FIG. 70 is a diagram illustrating wafer bowing during the growth of the non-emitting III-nitride semiconductor stacked structure or device shown in FIG. 69, and illustrates that, after forming the protrusions 44c and the material layer 45a on the HT-grown AlN layer 43k with air voids AV, at a growth starting point, both a state (Q) in which wafer bowing is further increased and a state (P) in which the bowing is reduced are exhibited.

FIG. 71 is a diagram illustrating yet another example of a non-emitting III-nitride semiconductor stacked structure or device according to the present disclosure. Here, unlike the stacked structure or device shown in FIG. 69, protrusions 44c are included in a first layer 43m, and there is less concern that air voids AV will extend to the upper part of the protrusions 44c, making it possible to reduce the thickness of an HT-grown AlN layer 43k on which a lot of tensile stress acts, that is, flexibility may be imparted to the growth condition of the HT-grown AlN layer 43k. It is obvious that a material layer 45a may be included on the protrusions 44c.

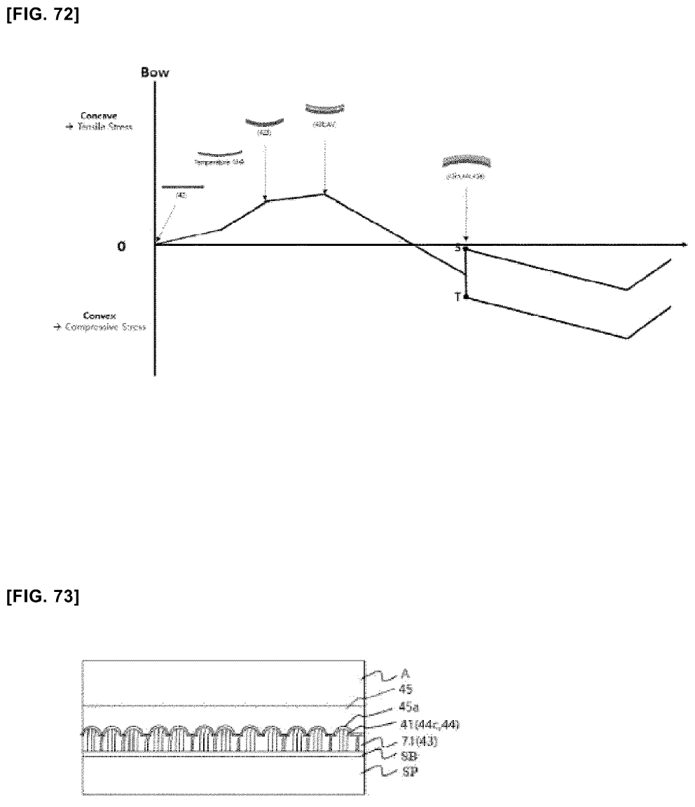

FIG. 72 is a diagram illustrating the bowing of a wafer during the growth of the non-emitting III-nitride semiconductor stacked structure or device shown in FIG. 70, in which the wafer bowing may be in a convex state after a first layer 43m, which is a stress release layer (the layer whose composition changes from a form close to AlN to a form close to GaN (e.g., the composition of Al decreases in the order 0.8→0.5→0.2)) grows. In such a wafer state, even when protrusions 44c and a material layer 45a are included, the formation of the protrusions 44c and the material layer 45a adjusts the state of a final wafer to a convex state regardless of whether the degree of wafer bowing is increased to a concave state (S) or the degree of wafer bowing is decreased to a convex state (T). It is not excluded to form the protrusions 44c under a second layer 43c and a channel layer 46.

While various methods of manufacturing non-emitting III-nitride semiconductor stacked structures or devices have been presented with reference to the previous examples, the examples shown in FIGS. 8 to 14 provide a method of reducing crystal defects, the examples shown in FIGS. 17 to 23 provide a method of reducing crystal defects using the protrusions 41 and the growth prevention films 44, the examples shown in FIGS. 24 and 25, the examples shown in FIGS. 33 to 40, and the examples shown in FIGS. 44 to 51 provide a method of removing the growth substrate 41 and attaching a new support substrate.

From the perspective of growth, in order to reduce crystal defects, using a GaN substrate, a SiC substrate, or a sapphire (Al2O3) substrate is more advantageous than the using a silicon (Si) substrate, but the GaN substrate and the SiC substrate are expensive, the sapphire substrate has disadvantages in terms of heat dissipation, and the Si substrate has disadvantages in terms of crystal defects. Therefore, considering all of the aspects of crystal defects, cost, and heat dissipation, a method of growing a non-emitting III-nitride semiconductor stacked structure using a sapphire substrate and then replacing the sapphire substrate with a Si support substrate will be examined below.

Referring again to FIG. 24, first, a protrusion base layer 71 or first buffer layer 43, a second buffer layer 45, and a non-emitting III-nitride semiconductor stacked structure A are formed on a growth substrate 42 (sapphire substrate). Protrusions 41 (44c, 44) are formed on a protrusion base layer 71 or first buffer layer 43, and a material layer 45a is formed thereon. It is obvious that the material layer 45a may be partially formed in the forms shown in FIGS. 22 and 23, and when the material layer 45a is formed in the form shown in FIG. 23, the material layer 45a may be formed of not only an Al-containing material such as AlN, AlNO, or AlO, which slows the growth rate of the second buffer layer 45, but also a dielectric material such as SiO2, or SiNx, which prevents the growth of the second buffer layer 45 on the protrusions 41 (44c, 44). Here, the configuration of the protrusion base 71 or first buffer layer 43 may be the configuration described above.

Next, as shown in FIG. 25, a temporary substrate S is attached to the non-emitting III nitride stacked structure A, and then the growth substrate 42 formed of sapphire is removed. The attachment of the temporary substrate S and the removal of the growth substrate 42 are described in detail in the examples shown in FIGS. 33 to 40, and the examples shown in FIGS. 44 to 51. As shown in FIG. 30, it is obvious that the necessary electrode formation work can be done in advance.

Next, as shown in FIG. 73, a support substrate SP formed of silicon is attached using a junction layer SB, and the temporary substrate S is removed. The composition of the junction layer SB and the method of removing the temporary substrate S are also described in detail in the examples shown in FIGS. 33 to 40, and the examples shown in FIGS. 44 to 51.

In the manufacturing process, the first buffer layer 43 itself may be omitted, the protrusions 41 (44c, 44) may be omitted, or the material layer 45a may be omitted, which is not preferable from the viewpoint of reducing crystal defects. Referring to FIG. 25, although it is not preferable from the viewpoint of removing the growth substrate 42, as shown in FIGS. 17 to 23, it is obvious to use the growth substrate 42 provided with protrusions 41, and therefore, there are 8 possible types of combinations (two cases in which the growth substrate 42 is provided or not provided with the protrusions 41; and four cases in which the growth substrate 42 only is provided with the first buffer layer 43, the growth substrate 42 is provided with the first buffer layer 43 and the protrusions 41 (44c, 44), the growth substrate 42 is provided with the first buffer layer 43, the protrusions 41 (44c, 44) and the material layer 45a, and the growth substrate 42 is provided with none of the first buffer layer 43, the protrusions 41 (44c, 44) and the material layer 45a. From the viewpoint of reducing crystal defects, it is preferable to have both a growth substrate 42 with protrusions 41, and a first buffer layer 43 with a material layer 45a and protrusions 41 (44c, 44). In addition, it is obvious that the examples of the configurations of the protrusions 41 and protrusion base layer 71, which are formed on the growth substrate 42, or the protrusions 41 (44c, 44) and the material layer 45a, which are formed on the first buffer layer 43, can be expanded to the forms shown in FIGS. 8 to 14. That is, the protrusions 41 formed on the growth substrate 42 may be configured in the forms shown in FIGS. 11 to 14, the protrusions 41 (44c, 44) and the material layer 45a, which are included on the protrusion base layer 71 or the first buffer layer 43, may be replaced with a growth prevention film or a growth inhibition film as shown in FIGS. 8 and 17.

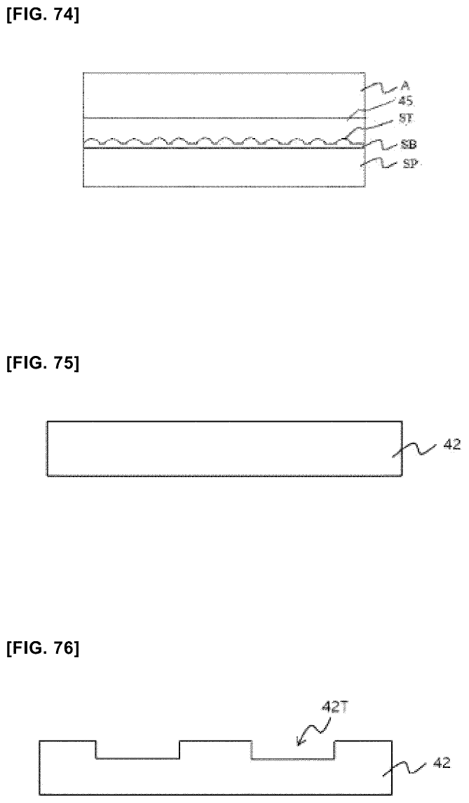

Referring again to FIG. 25, in the process of removing the growth substrate 42, as shown in FIG. 25, three conditions, for example, one condition in which the first buffer layer 43 is left as it is; another condition in which the material layer 45a is exposed by removing the first buffer layer 43; and the last condition in which the second buffer layer 45 is exposed by removing the first buffer layer 43 and the material layer 45a may be considered. These conditions can be combined into six combinations depending on whether a surface texture is imparted. As shown in FIG. 35, a surface texture may be given to the first buffer layer 43, and when the material layer 45a is exposed, a surface texture may be formed by the protrusions 41 (44c, 44) that are removed without a separate process, and even when the second buffer layer 45 is exposed (see FIG. 74), a surface texture ST may be formed without a separate process. When the growth substrate 42 is provided with the protrusions 41, it is easy to form a surface texture on the first buffer layer 43, and in some cases, a surface texture may be formed separately on the second buffer layer 45. By removing the first buffer layer 43 in which crystal defects such as multiple TDs 54, 55, and 56 are present as shown in FIG. 16, the crystal defect region is removed from the final stacked structure or device. When the protrusions 41 (44c, 44) are removed and the second buffer layer 45 is exposed, crystal defects present in the upper part of the protrusions 41 (44c, 44) (TDs 58, 59, 58a, 58b, 59a, and 59b present in the upper part of the protrusions 41 (44c, 44) as shown in FIGS. 18 to 20 may also be removed, so that the crystal defect region is further removed from the final stacked structure or device. The removal of the first buffer layer 43 formed of GaN, AlGaN, or AlN, the material layer 45a, and the second buffer layer 45 is preferably performed by dry etching with chloride (Cl2) or chlorine boride (BCl3) gas, but wet etching using an acidic or basic solution may also be applied.

FIGS. 75 to 87 are diagrams illustrating yet another example of a method of manufacturing a non-emitting III-nitride semiconductor stacked structure or device according to the present disclosure, and relate to another method of manufacturing a non-emitting III-nitride semiconductor stacked structure or device in the forms shown in FIGS. 50 and 51 (forms in which thermal paths are formed in the growth substrate 42 by means of the conductive material 97C).

First, as shown in FIG. 75, the growth substrate 42 (e.g., sapphire substrate) is prepared.

Next, as shown in FIG. 76, one or more trenches 42T are formed. Laser drilling may be used to form the trenches 42T, and the trenches 42T may be formed in a dot shape and/or a strip shape. The dot shape may be a circular, quadrangular, and hexagonal shape, and there is no limitation on its shape. For example, the trenches 42T may be formed to have a width of 50 μm or less, an interval of 50 μm or less, and a length of 100 μm or less.

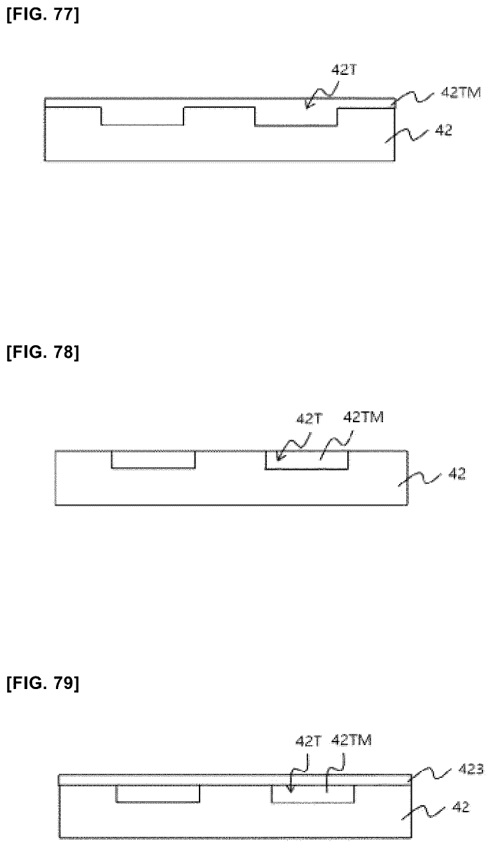

Next, as shown in FIG. 77, a trench-covering material 42TM is formed on the top surface of the growth substrate 42 to fill the trenches 42T. The trench-covering material 42TM may be a photoresist (PR), SOG, a resin containing a silicon (Si) component, or a composite paste containing an aluminum (Al) component, and may be formed by spin coating, dotting, screen printing, electrochemical deposition, or electrophoresis. According to an additional process, it is also possible to introduce an annealing process to solidify the trench-covering material 42TM or remove an organic component.

Preferably, as shown in FIG. 78, the trench-covering material 42TM formed on the growth substrate 42 is removed. For this removal process, dry etching such as ICP or RIE etching may be preferentially used, and depending on the type and process of forming the trench-covering material 42TM, mechanical polishing or mechanical-chemical polishing may also be used.

Next, as shown in FIG. 79, a seed layer 423 (e.g., AlN or AlNO) is formed. The seed layer 423 may be formed by a CVD (MOCVD, ALD, or MBE) or PVD (sputtering or PLD) method. Since the trench-covering material 42TM has to be maintained in the trenches 42T during the formation of the seed layer 423, the forming method is preferably performed at a lower temperature than the evaporation temperature of the trench-covering material 42TM. For example, when the trench-covering material 42TM is a PR, the seed layer 423 may be formed by a PVD method such as sputtering.

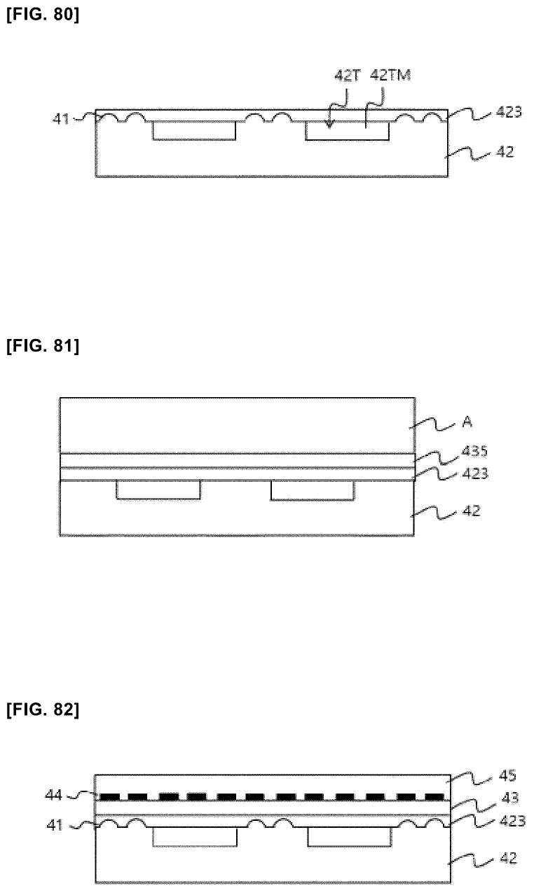

As shown in FIG. 80, to enhance the crystallinity of an III-nitride semiconductor to be used in film formation, it is obvious that protrusions 41 can be formed on the growth substrate 42.

Next, as shown in FIG. 81, a non-emitting III-nitride semiconductor stacked structure A is formed thereon. Preferably, a buffer layer 435 is formed on the seed layer 423, and a III-nitride semiconductor stacked structure A is formed.

As shown in FIG. 82, as in FIGS. 17 to 23, after forming protrusions 41 on the growth substrate 42, and forming the seed layer 423, a first buffer layer 43 and growth prevention films 44 may be formed thereon, a second buffer layer 45 may be formed thereon, and then a non-emitting III-nitride semiconductor stacked structure A may be formed. As described above, it is obvious that the growth prevention films 44 may be made of a different material (e.g., SiO2) from the first buffer layer 43, or the same material as the first buffer layer 43, and the protrusions 41 may be omitted.

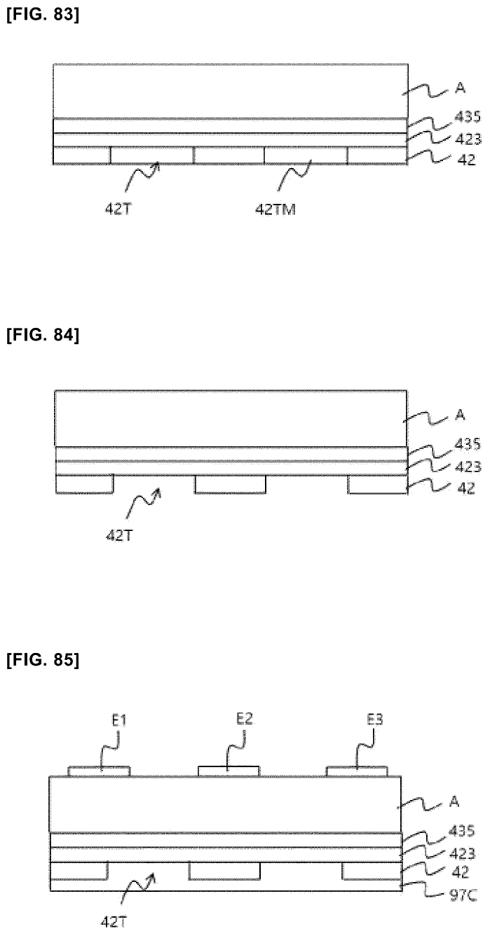

Next, as shown in FIG. 83, the trenches 42T and the trench-covering material 42TM are exposed by reducing the thickness of the growth substrate 42 on the side facing the non-emitting III-nitride semiconductor stacked structure A. In this process, a wrapping & polishing process may be used.

Next, as shown in FIG. 84, the trench-covering material 42TM is removed. In this process, a method for removal may be determined according to the type and process of forming the trench-covering material 42TM, dry etching such as ICP or RIE etching may be preferentially used, and a wet etching process using a selective etching solution may also be used.

On the other hand, after the process shown in FIG. 79, it is possible to remove the trench-covering material TM (e.g., a PR) through thermal treatment and proceed to the subsequent process (refer to U.S. Pat. No. 9,793,359). In this case, the process shown in FIG. 84 may be omitted or simplified.

Finally, as shown in FIG. 85, as in FIG. 50, thermal and/or electrical paths are formed by filling the trenches 42T with the conductive material 97C. In the non-emitting III-nitride semiconductor stacked structure A, depending on the device (D-mode HEMT, E-mode HEMT, or JFET), necessary electrodes E1, E2, and E3 may be included, the electrodes E1, E2, and E3 may be formed before or after the thickness reduction of the growth substrate 42, and by forming the electrode before the process of reducing the thickness of the growth substrate 42, the thick growth substrate 42 may serve as a support substrate to ensure the stability of the process. When the device is HEMT, the electrodes E1, E2, and E3 may be a source electrode, a gate electrode, and a drain electrode, respectively (see FIG. 41), and when the device is JFET, the electrode E1 and the electrode E3 may correspond to gate electrodes, the electrode E2 may correspond to a source electrode, and the conductive material 97C may correspond to a drain electrode (see FIG. 37).

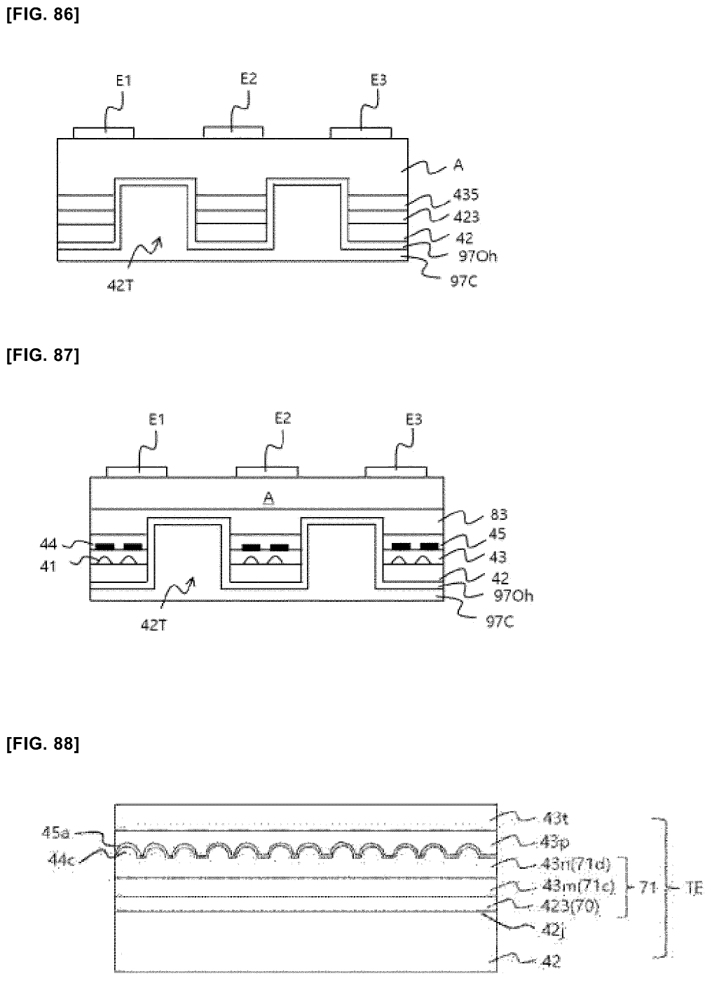

In addition, as shown in FIG. 86, in the process of removing the trench-covering material 42TM, to expand thermal paths or form electrical paths, the trenches 42T may be formed to extend to the buffer layer 435 or the non-emitting III nitride stacked structure A (see FIG. 51). This extension of the trenches 42T may be formed through dry etching. For example, when the device is JFET, it is possible to extend the trenches 42T to the drain region 83, preferably, to improve the ohmic properties of the drain region 83 and the conductive material 97C, it is possible to form an ohmic contact electrode 970h in the trenches 42T in advance. The ohmic contact electrode 97Oh may consist of, for example, four layers, the first layer may consist of Ti or Cr, which is a metal that has a small work function and excellent adhesive strength with non-emitting III-nitride semiconductor, and is relatively easy to form a metal nitride during thermal treatment, the second layer may consist of Al, V, or Re, which is a metal that has a small work function and is relatively easy to form a metal nitride during thermal treatment, the third layer may consist of Pt, Ni, W, Mo, Ti, Cr, TiW, or NiCr, which can prevent material movement when a high temperature or high power is applied due to a high atomic packing fraction and a high melting point, and the fourth layer may consist of Au or Cu, which is easy to be connected to external parts.

In FIG. 87, a combined form of the example shown in FIG. 82 and the example shown in FIG. 86 is shown, and trenches 42T are extended to a drain region 83 through protrusions 41 and growth prevention films 44. For convenience of description, the seed layer 423 was omitted.

FIGS. 88 to 92 are diagrams illustrating yet another example of a III-nitride semiconductor stacked structure or device according to the present disclosure, and show technology that can be applied to III-nitride semiconductor optical devices (e.g., light emitting devices (LDs and LEDs), and photodiodes (solar cells)) other than non-emitting III-nitride semiconductor stacked structures or light receiving devices (e.g., diodes and transistors) unlike the previous examples, and uses a Si substrate or SiC substrate as the growth substrate 42.

As shown in FIG. 88, the III-nitride semiconductor stacked structure includes a growth substrate 42 (e. g., a Si substrate or SiC substrate), a seed layer 423, a first layer 43m, a second layer 43n, a stress adjustment layer 43p, and an uppermost layer 43t. Preferably, the III-nitride semiconductor stacked structure includes a pre-seeding layer 42j.

Unlike the example shown in FIG. 71, the AlN layer 43k is omitted, protrusions 44c are formed on the second layer 43n, and an AlN, AlNO, or AlO material layer 45a is included between the second layer 43n on which the protrusions 44c are formed and the stress adjustment layer 43p. The process of forming the second layer 43n provided with the protrusions 44c is the same as the process of forming a protrusion base layer 71 including a seed layer 70, a first layer 71c and a second layer 71d, shown in Case I of FIG. 14. The function of the AlN, AlNO, or AlO material layer 45a has been described in relation to the examples shown in FIGS. 21 to 23, and with regard to the growth of the first layer 43m and the growth of the stress control layer 43p, the AlN, AlNO, or AlO material layer 45a may serve as a seed layer like the seed layer 423. While the seed layer 423 may be formed of in-situ AlN, ex-situ AlN or ex-situ AlNO, or AlO, the AlN, AlNO, or AlO material layer 45a is preferably formed ex-situ in terms of protection of the second layer 43n on which the protrusions 44c are formed.

For example, the seed layer 423 may be formed of AlN with a thickness of 50 nm or less at a low temperature (500 to 900° C.) using a MOCVD device. The AlN, AlNO, or AlO material layer 45a may be deposited to a thickness of 50 nm or less using a PVD (sputtering, ALD, or PLD) device. In the example shown in FIG. 88, the seed layer 423 may be referred to as a first seed layer, and the AlN, AlNO, or AlO material layer 45a may be referred to as a second seed layer.

In the example shown in FIG. 88, the III nitride stacked structure serves as a base, that is, a template TE of a device to be formed thereon, and from this point of view, it is preferable that the uppermost layer 43t consists of Ga-rich AlGaInN, particularly, GaN. However, it is obvious that, according to the requirements of a III-nitride semiconductor device to be implemented thereon, the uppermost layer 43t may be doped with n-type or p-type impurities (e.g., Si, or Mg) or include some Group III elements (e.g., In and Al). The thickness of the uppermost layer 43t is not particularly limited, but it is preferable that the uppermost layer 43t has a thickness that minimizes stress and does not cause cracking to grow the active layer of a non-emitting or light emitting device (e.g., an HEMT or LED) continuously grown afterwards with high quality, and the active layer is conventionally grown from a minimum of 500 nanometers (nm) or more to a maximum of 3 micrometers (μm) or less.

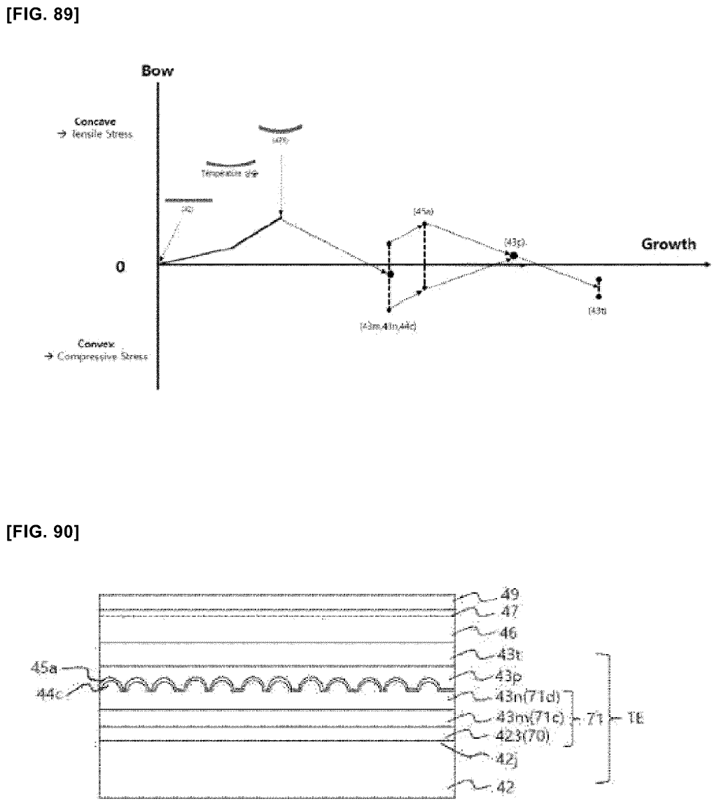

Referring to FIG. 89, after forming the seed layer 423, the wafer becomes concave as shown in FIG. 72, and to address this, a first layer 43m, which is a stress release layer (a layer whose composition changes from a form close to AlN to a form close to GaN (e.g., the composition of Al is reduced in the order 0.8→0.5→0.2)), is required. In the example shown in FIG. 88, it is obvious that the first layer 43m may have a thickness of 1 μm or less, may consist of a Single layer of AlGaN, AlGaN in which the Al composition is decreased in a gradual or stepwise manner, or a multilayer structure or superlattice structure (AlN/GaN, AlN/AlGaN, or AlxGa1−xN/AlyGa1−yN), and may be doped with n-type or p-type impurities (e.g., Si and Mg). In any case, since the wafer is placed at room temperature to form protrusions 44c after the growth of the second layer 43n, the wafer is preferably in a convex form such that cracks do not occur after the growth of the second layer 43n (e.g., GaN), and the first layer 43m should have an Al composition that reduces the stress of the wafer to prevent cracks in the wafer, wherein the cracks are generated due to an excessively concave wafer after the growth of the second layer 43n from the state in which the seed layer 423 is formed, and should have the overall composition of AlxGa1−xN (0<x<1).

In addition, after forming the protrusions 44c, wafer bowing may increase or decrease, and the formation of an AlN, AlNO, or AlO material layer or second seed layer 45a leads to concave wafer bowing like the formation of the first seed layer 423. Since no cracks should occur after forming the uppermost layer 43t, the wafer should not be excessively concave, and preferably, should be convex, these conditions have to be satisfied after forming the uppermost layer 43t by means of the stress adjustment layer 43p (AlGaInN), and thus the stress adjustment layer 43p has a composition that increases or decreases the stress of the wafer according to the bowing state of the wafer after forming the second seed layer 45a. The stress adjustment layer 45p may have a monolayer structure, a multilayer structure, or a superlattice structure, may have a gradual or stepwise change in composition, and may consist of AlN, an Al-rich III nitride (e.g., Al—AlGaN), or a Ga-rich III nitride (e.g., Ga-rich AlGaN or Ga-rich GaInN). The thickness of the stress adjustment layer 43p is preferably at least greater than the height of the protrusions 44c formed on the upper part of the second layer 43n. To inhibit/minimize crystal defects such as TDs occurring in the thin film layer including the growth substrate 42 below the second layer 43n in a growth direction by the ELOG thin film growth mode on the periphery of the protrusions 44c present on the upper part of the second layer 43n in 360° directions, the stress adjustment layer 43p is preferably grown higher than the height of the protrusions 44c and planarized. For example, the stress adjustment layer 43p may be grown to a thickness of 100 nm to 2 μm.

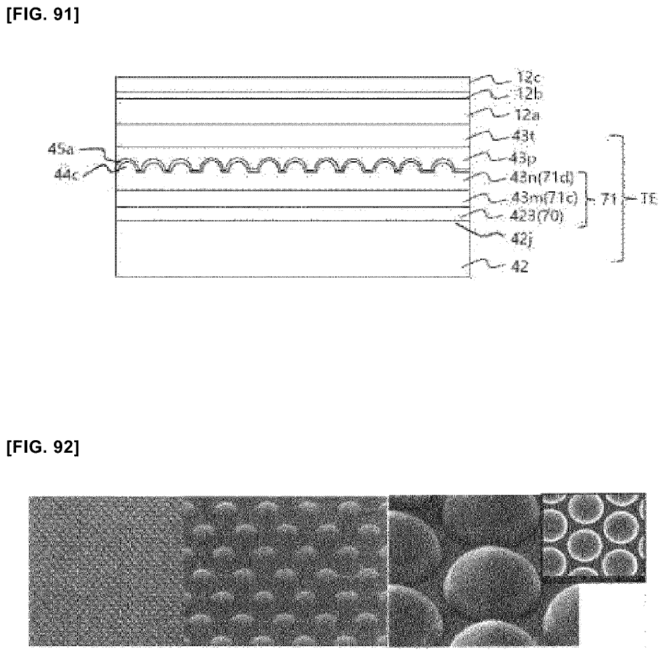

In FIG. 90, the example of an HEMT device that includes a channel layer 46, a 2DEG 47, and a barrier layer 49 on the III nitride stacked structure or template TE shown in FIG. 88 is illustrated, and in FIG. 91, the example of an LED device that includes an n-type III-nitride semiconductor region 12a as shown in FIG. 6, an active region 12b, and a p-type III-nitride semiconductor region 12c on the III nitride stacked structure or template TE shown in FIG. 88 is illustrated. In FIG. 92, an actual image of the protrusions 44c (see FIG. 88) formed on the second layer 43n is shown, and it can be seen that the hemispherical protrusions 44c a width of 2.5 μm, a height of 1.5 μm, and an interval of 0.45 μm are well formed.

Hereinafter, various embodiments of the present disclosure will be described.

(1) A method of manufacturing a non-emitting III-nitride semiconductor stacked structure, which includes preparing a growth substrate containing silicon (Si); forming a plurality of protrusions on the growth substrate; growing a first buffer layer to cover the plurality of protrusions on the growth substrate; forming a plurality of growth prevention films on the first buffer layer; growing a second buffer layer from the first buffer layer exposed through the growth prevention films; and forming a non-emitting III-nitride semiconductor stacked structure on the second buffer layer.

(2) In this method, in the step of forming growth prevention films, a plurality of growth prevention films are formed on the upper part of each protrusion and between the protrusions.

(3) In this method, the plurality of protrusions and the growth substrate are formed

of the same material.

(4) In this method, the Si-containing growth substrate is one of a Si growth substrate and a SiC growth substrate.

(5) In this method, the plurality of protrusions and the growth substrate are formed of different materials.

(6) Prior to the step of forming a plurality of protrusions, this method further includes forming a protrusion base layer, and the plurality of protrusions are formed by etching the protrusion base layer.

(7) In this method, the protrusion base layer is composed of a seed layer formed on the growth substrate and a III-nitride semiconductor layer formed on the seed layer.

(8) In this method, the III-nitride semiconductor layer of the protrusion base layer

is exposed by etching.

(9) In this method, the seed layer of the protrusion base layer is exposed by etching.

(10) Prior to the step of forming a plurality of protrusions, this method further includes forming a protrusion base layer, and the plurality of protrusions are formed by the lift-off of the protrusion base layer.

(11) This method further includes forming a seed layer that covers the lifted-off protrusion base layer and the growth substrate exposed through the lift-off.

(12) A method of manufacturing a non-emitting III-nitride semiconductor stacked structure, which includes preparing a growth substrate; forming a plurality of protrusions on the growth substrate; growing a first buffer layer to cover the plurality of protrusions on the growth substrate; forming a plurality of growth inhibition films on the first buffer layer; growing a second buffer layer from the first buffer layer exposed through the plurality of growth inhibition films; and forming a non-emitting III-nitride semiconductor stacked structure on the second buffer layer.

(13) In this method, in the step of forming a plurality of growth inhibition films, a plurality of growth inhibition films are formed on the upper part of each protrusion and between the protrusions.

(14) In this method, the plurality of protrusions and the growth substrate are formed of the same material.

(15) In this method, the plurality of growth inhibition films includes a dielectric material.

(16) In this method, a second buffer layer can be grown from the plurality of growth inhibition films. Growth rate of a second buffer layer grown from the plurality of growth inhibition films is lower than growth rate of a second buffer layer grown from a first buffer layer.

(17) In this method, the plurality of growth inhibition films include one of AlN, AlNO, and AlO.

(18) In this method, the plurality of growth inhibition films are formed of a material for forming the first buffer layer.

(19) Prior to the step of growing a second buffer layer, this method further includes forming a material layer that allows the growth rate of the second buffer layer to be lower than the rate of growing the second buffer layer from the first buffer layer.

(20) Prior to the step of growing a second buffer layer, this method further includes forming a material layer that allows the growth rate of the second buffer layer to be lower than the rate of growing the second buffer layer from the first buffer layer.

(21) In this method, the plurality of growth inhibition films include one of AlN, AlNO, and AlO.

(22) A method of manufacturing a non-emitting III-nitride semiconductor stacked structure, which includes preparing a growth substrate; growing a first buffer layer on the growth substrate; forming a plurality of protrusions formed of the same material as the first buffer layer on the first buffer layer; growing a second buffer layer on the first buffer layer, forming a non-emitting III-nitride semiconductor stacked structure on the second buffer layer; and forming a material layer that allows the growth of the second buffer layer to be slower or prevented on the plurality of protrusions before growing the second buffer layer.

(23) In this method, the material layer is formed of a material that slows the growth of the second buffer layer, and is formed over the entire first buffer layer on which the plurality of protrusions are formed.

(24) In this method, the first buffer layer is composed of a seed layer formed on the growth substrate and a III-nitride semiconductor layer formed on the seed layer.

(25) This method further includes separating the growth substrate from the non-emitting III-nitride semiconductor stacked structure side.

(26) A non-emitting III-nitride semiconductor stacked structure, which includes a drain region; a drift region; and a gate region, which are sequentially stacked; a support substrate electrically connected to the drain region; a gate electrode electrically connected to the gate region; a source electrode electrically connected to a channel formed by the drift region exposed through the gate region; a passivation layer that covers the entire stacked structure where the gate electrode and the source electrode are located and in which a plurality of openings are formed; a gate electrode for bonding, which is electrically connected to the gate electrode by one of the plurality of openings; and a source electrode for bonding, which is electrically connected to the source electrode by another of the plurality of openings.

(27) In this stacked structure, the support substrate is formed of the same material as the growth substrate and includes a plurality of thermal and electrical paths, and the stacked structure further includes a drain electrode for bonding under the support substrate.

(28) In this stacked structure, the support substrate is formed of sapphire.

(29) In this stacked structure, the support substrate is formed of AlN.

(30) In this stacked structure, the support substrate is formed of silicon (Si).

(31) A method of manufacturing a non-emitting III-nitride semiconductor stacked structure, which includes forming a non-emitting III nitride stacked structure on a growth substrate; attaching a temporary substrate to the side of the stacked structure facing the growth substrate; removing the growth substrate; forming a multilayer thin film including an electrically insulating ceramic layer and a metal layer on the side of the stacked structure from which the growth substrate is removed in the order of the ceramic layer and the metal layer; attaching a support substrate to the multilayer thin film; and removing the temporary substrate.

(32) The supporting substrate includes a thermal path, and this method further includes reducing the thickness of the support substrate; and forming a bonding pad on the support substrate with the reduced thickness.

(33) This method further includes forming at least one electrode on the stacked structure from which the temporary substrate is removed.

(34) A stacked structure for a non-emitting III-nitride semiconductor, which includes a support substrate; a multilayer thin film consisting of an electrically insulating ceramic layer and a metal layer, which are sequentially stacked; a non-emitting III-nitride semiconductor region that consists of a buffer layer, a channel layer, and a barrier layer; a gate electrode, a source electrode, and a drain electrode, which are electrically connected to the non-emitting III-nitride semiconductor region; a passivation layer that covers the non-emitting III-nitride semiconductor region where the source electrode, the drain electrode and the gate electrode are located and exposes the source electrode, the drain electrode, and the gate electrode to enable electrical connection to the outside; and a field plate disposed on the upper part of the passivation layer to be electrically connected to one of the source electrode and the gate electrode.

(35) A method of manufacturing a non-emitting III-nitride semiconductor stacked structure, which includes forming a non-emitting III nitride stacked structure on a non-conductive growth substrate; attaching a temporary substrate to the side of the stacked structure facing the growth substrate; reducing the thickness of the growth substrate; attaching a support substrate to the thickness-reduced growth substrate; and removing the temporary substrate.

(36) The support substrate includes a thermal path, and this method further includes, prior to the step of removing the temporary substrate, reducing the thickness of the support substrate to expose the thermal path.

(37) In this method, the support substrate is attached to the growth substrate with a reduced thickness by means of a junction layer.

(38) This method further includes forming a thermal path in the growth substrate with a reduced thickness.

(39) In this method, the thermal path extends to the non-emitting III nitride stacked structure.

(40) In this method, the growth substrate is a sapphire substrate or a Si substrate.

(41) A method of manufacturing a non-emitting III-nitride semiconductor stacked structure, which includes sequentially growing a drain region and a drift region; forming a channel by removing a part of the drift region; and regrowing a gate region in the partially-removed drift region, and further includes forming an interlayer between the gate region and the drift region before the regrowing.

(42) In this method, the interlayer is formed on the bottom surface of the drift region that has been removed and exposed and side surfaces of the channel.

(43) This method further includes reducing the step difference between the gate region and the drift region.

(44) In the reducing step, the interlayer is removed to expose the side surfaces of the upper part of the channel.

(45) A method of manufacturing a non-emitting III-nitride semiconductor stacked structure, which includes preparing a growth substrate including a plurality of protrusions; growing a first buffer layer to cover the plurality of protrusions on the growth substrate; forming a plurality of growth prevention films without an alignment process with respect to the plurality of protrusions on the first buffer layer, and growing a second buffer layer from the first buffer layer exposed through the plurality of growth prevention films.

(46) In this method, each of the growth prevention films has a horizontal width and a vertical width, wherein the horizontal width and the vertical width are determined by the density of TDs in the first buffer layer. Here, the horizontal width and the vertical width refer to the maximum widths in the horizontal and vertical directions. When the growth prevention film has a circular shape, both widths are identical.

(47) In this method, each of the growth prevention films has a horizontal width and a vertical width, wherein at least one of the horizontal and vertical widths is the same as or longer than the average distance between TDs in the first buffer layer.

(48) In this method, each of the growth prevention films has a horizontal width and a vertical width, the plurality of protrusions have a constant interval, horizontal width, and vertical width, and the horizontal and vertical widths are determined by the constant interval, horizontal width, and vertical width.

(49) In this method, each of the growth prevention films has a horizontal width and a vertical width, the plurality of protrusions have a constant interval, horizontal width, and vertical width, and at least one of the horizontal and vertical widths is the same as or longer than the constant horizontal and vertical widths.

(50) In this method, each of the growth prevention films has a horizontal width and a vertical width, the plurality of protrusions have a constant interval, horizontal width, and vertical width, and at least one of the horizontal and vertical widths is the same as or longer than the constant interval.

(51) Prior to the step of forming a growth prevention film, this method further includes forming an SiNx nano mask on the first buffer layer.

(52) This method further includes forming a non-emitting III-nitride semiconductor stacked structure on the second buffer layer.

(53) A method of manufacturing a non-emitting III-nitride semiconductor stacked structure, which includes forming a channel layer, a 2DEG, a barrier layer, and a gate electrode on a growth substrate; attaching a temporary substrate using a junction layer; removing the growth substrate; and forming a source electrode and a drain electrode on the channel layer from which the growth substrate is removed.

(54) This method further includes forming an insulating layer between the source

electrode and the drain electrode.

(55) In this method, the gate electrode is formed over the entire barrier layer.

(56) In this method, the gate electrode is formed closer to the source electrode than the drain electrode.

(57) In this method, the gate electrode is formed to overlap at least a part of the

upper part of the source electrode.

(58) This method further includes attaching the source electrode and the drain electrode to the support substrate; and removing the temporary substrate.

(59) In this method, in the step of removing the temporary substrate, the gate electrode is exposed.

(60) A method of manufacturing a non-emitting III-nitride semiconductor stacked structure, which includes forming a seed layer formed of AlN at a first temperature on a growth substate formed of silicon (Si); forming an AlN layer at a second temperature higher than the first temperature on the seed layer; forming a channel layer, a 2DEG, and a barrier layer on the AlN layer; and forming at least one of air voids and protrusions before forming the channel layer.

(61) In this method, the protrusions are formed on the AlN layer.

(62) In this method, the air voids are formed in the AlN layer.

(63) In this method, the air voids are formed at a third temperature that is higher than the first temperature and lower than the second temperature.

(64) Before forming a channel layer, this method further includes forming a strain control layer that releases the strain caused by the lattice constant difference between the AlN layer and the channel layer.

(65) In this method, the protrusions are formed in the strain control layer.

(66) This method further includes forming a material layer on the protrusions.

(67) A method of manufacturing a non-emitting III-nitride semiconductor device, which includes growing a non-emitting III-nitride semiconductor stacked structure on a growth substrate formed of sapphire; attaching a temporary substrate to the non-emitting III-nitride semiconductor stacked structure on the side facing the growth substrate; removing the growth substrate from the non-emitting III-nitride semiconductor stacked structure; attaching a support substrate formed of silicon to the non-emitting III-nitride semiconductor stacked structure on the side from which the growth substrate is removed; and removing the temporary substrate from the non-emitting III-nitride semiconductor stacked structure. Alternatively, as the growth substrate, instead of the sapphire substrate, a recently-introduced ScAlMgO4 (SAM) single-crystal substrate, which can minimize crystal defects during the growth process, can be used.

(68) This method further includes, prior to the growth step, growing the first buffer layer where a growth inhibition film is formed on the upper part; and growing the second buffer layer on the first buffer layer to cover the growth inhibition film.

(69) Prior to the step of growing a second buffer layer, this method further includes forming a material layer that blocks and reduces TDs exposed on the surface of the first buffer layer.

(70) Prior to the step of attaching the support substrate, this method further includes removing a part of the first buffer layer.

(71) Prior to the step of attaching the support substrate, this method further includes removing all of the first buffer layer.

(72) Prior to the step of attaching the support substrate, this method further includes removing the first buffer layer to expose the material layer.

(73) Prior to the step of attaching the support substrate, this method further includes removing a part of the first buffer layer, the material layer, and the second buffer layer.

(74) Prior to the step of attaching the support substrate, this method further includes removing a part of the first buffer layer, the material layer, and the second buffer layer, and imparting a surface texture to the second buffer layer.

(75) In this method, protrusions are formed on the growth substrate.

(76) A method of manufacturing a non-emitting III-nitride semiconductor device, which includes forming a trench in one surface of a growth substrate; filling the trench with a trench-covering material; forming a seed layer on one surface of the growth substate while filling the trench with the trench-covering material; forming a non-emitting III-nitride semiconductor stacked structure on the seed layer; exposing the trench by reducing the thickness of the growth substrate; and forming a conductive material in the trench from which the trench-covering material is removed.

(77) In this method, the seed layer is formed by a PVD method, and the non-emitting III-nitride semiconductor stacked structure is formed by a CVD method.

(78) In this method, the seed layer consists of AlN or AlNO.

(79) In this method, the trench-covering material is formed by spin coating.

(80) In this method, the trenches are formed by laser drilling.

(81) In this method, protrusions are formed on the growth substrate.

(82) In this method, between the growth substrate and the non-emitting III-nitride semiconductor stacked structure, a growth prevention film spaced apart from the growth substrate is formed.

(83) In this method, a source electrode and a gate electrode are formed on the non-emitting III-nitride semiconductor stacked structure, and the conductive material forms a drain electrode.

(84) In this method, the trenches extend to the non-emitting III-nitride semiconductor stacked structure.

(85) In this method, the trenches extend to the non-emitting III-nitride semiconductor stacked structure.

(86) In this method, between the growth substrate and the non-emitting III-nitride semiconductor stacked structure, at least one of the protrusions formed on the growth substrate and the growth prevention film spaced apart from the growth substrate are included, and the trenches extend to the non-emitting III-nitride semiconductor stacked structure through them.

(87) A method of manufacturing a III-nitride semiconductor stacked structure that includes an uppermost layer, which includes forming a first seed layer on a growth substrate, wherein the first seed layer has a composition that allows the growth substrate to have a concave shape; forming a first layer on the first seed layer, wherein the first layer has a composition that allows the growth substrate on which the first seed layer is formed to be less concave; forming a second layer of a Ga-rich III-nitride semiconductor on the first layer; forming a plurality of protrusions on the second layer; forming a second seed layer on the second layer on which the plurality of protrusions are formed, wherein the second seed layer has a composition that applies stress such that the growth substrate on which the second layer provided with the plurality of protrusions is formed is concave; forming a stress adjustment layer on the second seed layer, wherein the stress adjustment layer has an Al composition that releases or strengthens stress depending on a bowing state of the growth substrate on which the second seed layer is formed to prevent cracks in the stacked structure after forming an uppermost layer; and forming an uppermost layer of a Ga-rich III-nitride semiconductor on the stress adjustment layer. Here, Ga-rich means that Ga accounts for 50% or more of the entire composition, and Al-rich means that Al accounts for 50% or more of the entire composition.

(88) In this method, the first seed layer is formed by a MOCVD method.

(89) In this method, the first seed layer consists of one of AlN, AlNO, and AlO.

(90) In this method, the first layer consists of AlxGa1−xN (0<x<1).

(91) In this method, the second layer consists of GaN.

(92) In this method, the second seed layer consists of one of AlN, AlNO, and AlO.

(93) In this method, the second seed layer is formed by a PVD method.

(94) In this method, the uppermost layer consists of GaN.

(95) In this method, the stress adjustment layer adjusts the Al composition to inhibit cracks in the stacked structure between the second seed layer consisting of one of AlN, AlNO, and AlO and the uppermost layer consisting of GaN.

(96) In this method, the growth substrate is a Si substrate or a SiC substrate.

According to one non-emitting III-nitride semiconductor stacked structure or device of the present disclosure, a stacked structure or device having a TDD of 107/cm2 or less may be implemented.

According to another non-emitting III-nitride semiconductor stacked structure or device of the present disclosure, a vertical JFET with a novel form may be implemented.

According to still another non-emitting III-nitride semiconductor stacked structure or device of the present disclosure, a vertical JFET having a TDD of 107/cm2 or less may be implemented.

1. A method of manufacturing a non-emitting III-nitride semiconductor stacked structure, comprising:
preparing a growth substrate containing silicon (Si);
forming a plurality of protrusions on the growth substrate;
growing a first buffer layer to cover the plurality of protrusions on the growth substrate;
forming a plurality of growth prevention films on the first buffer layer;
growing a second buffer layer from the first buffer layer exposed through the growth prevention films; and
forming a non-emitting III-nitride semiconductor stacked structure on the second buffer layer.

2. The method of claim 1, wherein, in the forming of a growth prevention film, a plurality of growth prevention films are formed on the upper part of each protrusion and between the protrusions.

3. The method of claim 1, wherein the plurality of protrusions are formed of the same material as the growth substrate.

4. The method of claim 3, wherein the silicon (Si)-containing growth substrate is one of a Si growth substrate and a SiC growth substrate.

5. The method of claim 1, wherein the plurality of protrusions are formed of a different material from the growth substrate.

6. The method of claim 5, further comprising, prior to the forming of a plurality of protrusions, forming a protrusion base layer, wherein the plurality of protrusions are formed by etching the protrusion base layer.

7. The method of claim 6, wherein the protrusion base layer is composed of a seed layer formed on the growth substrate and a III-nitride semiconductor layer formed on the seed layer.

8. The method of claim 7, wherein the III-nitride semiconductor layer of the protrusion base layer is exposed by etching.

9. The method of claim 7, wherein the seed layer of the protrusion base layer is exposed by etching.

10. The method of claim 5, further comprising, prior to the forming of a plurality of protrusions, forming a protrusion base layer, wherein the plurality of protrusions are formed by lifting off the protrusion base layer.

11. The method of claim 10, further comprising forming a seed layer that covers the lifted-off protrusion base layer and the growth substrate exposed by the lift-off.
